(19) United States
(12) Patent Application Publication
(10) Pub. No.: US 2024/0204103 A1
(43) Pub. Date: Jun. 20, 2024

(54) TRANSISTOR GATE-CHANNEL ARRANGEMENTS WITH MULTIPLE DIPOLE MATERIALS

(71) Applicant: Intel Corporation, Santa Clara, CA (US)

(72) Inventors: Rohit Galatage, Hillsboro, OR (US); Cheng-Ying Huang, Portland, OR (US); Dan S. Lavric, Portland, OR (US); Sarah Atanasov, Beaverton, OR (US); Shao Ming Koh, Tigard, OR (US); Jack T. Kavalieros, Portland, OR (US); Marko Radosavljevic, Portland, OR (US); Mauro J. Kobrinsky, Portland, OR (US); Jami Wiedemer, Scappoose, OR (US); Munzarin Qayyum, Hillsboro, OR (US); Evan Clinton, Carrollton, GA (US)

(73) Assignee: Intel Corporation, Santa Clara, CA (US)

(21) Appl. No.: 18/065,657

(22) Filed: Dec. 14, 2022

(51) Int. Cl. H01L 29/78; H01L 29/06; H01L 29/423; H01L 29/49

(52) U.S. Cl. CPC H01L 29/785; H01L 29/0669; H01L 29/42392; H01L 29/49; H01L 2029/7858

(57) ABSTRACT

Disclosed herein are transistor gate-channel arrangements with transistor gate stacks that include multiple dipole materials, and related methods and devices. For example, in some embodiments, a transistor gate-channel arrangement may include a channel material and a transistor gate stack. The transistor gate stack may include a gate electrode material and a gate dielectric material between the gate electrode material and the channel material, where the gate dielectric material includes a first dipole material and a second dipole material where one of the first and second dipole materials is a P-shifter dipole material and the other one is an N-shifter dipole material.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each contact becomes increasingly significant. Careful design of transistors may help with such an optimization.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional side view of a transistor gate-channel arrangement including a gate stack with multiple dipole materials, in accordance with various embodiments.

FIGS. 2-6 are cross-sectional side views of example single-gate transistors including a transistor gate stack with multiple dipole materials, in accordance with various embodiments.

FIGS. 7A and 7B are perspective and cross-sectional side views, respectively, of an example fin-based field-effect transistor (FinFET) including a transistor gate stack with multiple dipole materials, in accordance with various embodiments.

FIGS. 8A and 8B are perspective and cross-sectional side views, respectively, of an example gate all-around (GAA) transistor including a transistor gate stack with multiple dipole materials, in accordance with various embodiments.

FIGS. 9-10 are cross-sectional side views of example IC devices with N-type and P-type GAA transistors with gate stacks with multiple dipole materials, in accordance with various embodiments.

FIG. 11 is a flow diagram of an example method of manufacturing a transistor gate stack with multiple dipole materials, in accordance with various embodiments.

FIGS. 12A-12H illustrates cross-sectional side views of example transistor gate-channel arrangements after various processes of the method of FIG. 11, in accordance with various embodiments.

FIGS. 13A and 13B are top views of a wafer and dies that may include one or more transistor gate stacks with multiple dipole materials in accordance with any of the embodiments disclosed herein.

FIG. 14 is a cross-sectional side view of an IC device that may include one or more transistor gate stacks with multiple dipole materials in accordance with any of the embodiments disclosed herein.

FIG. 15 is a cross-sectional side view of an IC device assembly that may include one or more transistor gate stacks with multiple dipole materials in accordance with any of the embodiments disclosed herein.

FIG. 16 is a block diagram of an example computing device that may include one or more transistor gate stacks with multiple dipole materials in accordance with any of the embodiments disclosed herein.

FIG. 17 is a block diagram of an example processing device that may include one or more transistor gate stacks with multiple dipole materials in accordance with any of the embodiments disclosed herein.

### DETAILED DESCRIPTION

Disclosed herein are transistor gate-channel arrangements with transistor gate stacks that include multiple dipole materials, and related methods and devices. The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

For purposes of illustrating transistor gate stack with multiple dipole materials and associated arrangements (e.g., transistor gate-channel arrangements with multiple dipole materials) and devices (e.g., IC devices implementing transistor gate stacks with multiple dipole materials) as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

The performance of a transistor may depend on the number of factors. For example, some transistors include gates that include a gate insulator, e.g., a gate dielectric such as a high-k dielectric, between a gate electrode and a semiconducting channel material. In such transistors, a stack of a gate insulator and a gate electrode material is typically referred to as a “transistor gate stack” and careful selection of the gate insulator is important for optimal performance. For example, threshold voltage of a transistor is a parameter that may be tuned by careful selection of a gate insulator used in the transistor gate stack. To that end, use of dipole materials has been explored in the past where inclusion of atoms of a dipole material in a gate dielectric material of a transistor leads to formation of interfacial dipoles (hence the name “dipole material”) and, consequently, to change in the threshold voltage of the transistor. A dipole material that lowers the threshold voltage of a P-type metal-oxide-semiconductor (PMOS) transistor is referred to as a “P-shifter dipole material” (or, simply, as a “P-shifter”), while a dipole material that lowers the threshold voltage of an N-type metal-oxide-semiconductor (NMOS) transistor is referred to as an “N-shifter dipole material” (or, simply, as an “N-shifter”). A manufacturing process for tuning threshold voltages of different transistors of an IC device by different amounts and/or in different directions (e.g., increasing or decreasing) then involves applying various masks to ensure that one dipole material (e.g., a P-shifter) is included in gate stacks of a first subset of transistors of the IC device, a second dipole material (e.g., an N-shifter) is included in gate stacks of a second subset of transistors of the IC device, and so on.

Inventors of the present disclosure realized that conventional implementations where dipoles materials are used do not allow sufficient versatility in threshold voltage tuning that may be needed for IC devices implementing large arrays of transistors such as stacks of GAA transistors. In particular, as described above, conventional implementations use only one type of a dipole material in a gate stack of a given transistor, e.g., either a P-shifter or an N-shifter. In contrast, embodiments of the present disclosure are based on recognition that using multiple types of dipole materials in a gate stack of a given transistor may be advantageous because it would allow tuning threshold voltages of different transistors by different amounts and/or in different directions while reducing complexity of the manufacturing process, e.g., reducing the number of masks and/or deposition steps used. For example, in some embodiments, transistor gate-channel arrangement may include a channel material and a transistor gate stack. The transistor gate stack may include a gate electrode material and a gate dielectric material between the gate electrode material and the channel material, where the gate dielectric material includes a first dipole material having a first material composition and a second dipole material having a second material composition, the second material composition being different from the second material composition. For example, the first dipole material may be a P-shifter while the second dipole material may be an N-shifter, or both the first and second dipole materials may be either a P-shifter or an N-shifter but may include different materials.

Transistor gate-channel arrangements as described herein, in particular transistor gate-channel arrangements with multiple dipole materials, may be included in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. In some embodiments, IC devices as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC devices as described herein may be included in memory devices or circuits. In some embodiments, IC devices as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations.

In the following detailed description, various aspects of the illustrative implementations may be described using terms commonly employed by those skilled in the art to convey the substance of their work to others skilled in the art. For example, in context of source/drain (S/D) regions of a transistor, the term “region” may be used interchangeably with the terms “contact” and “terminal” of a transistor. In another example, as used herein, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” “sulfide,” etc. refer to compounds containing, respectively, oxygen, carbon, nitrogen, sulfur, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

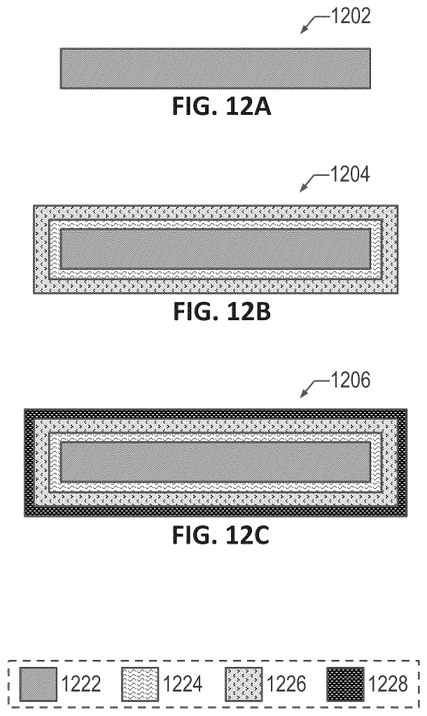

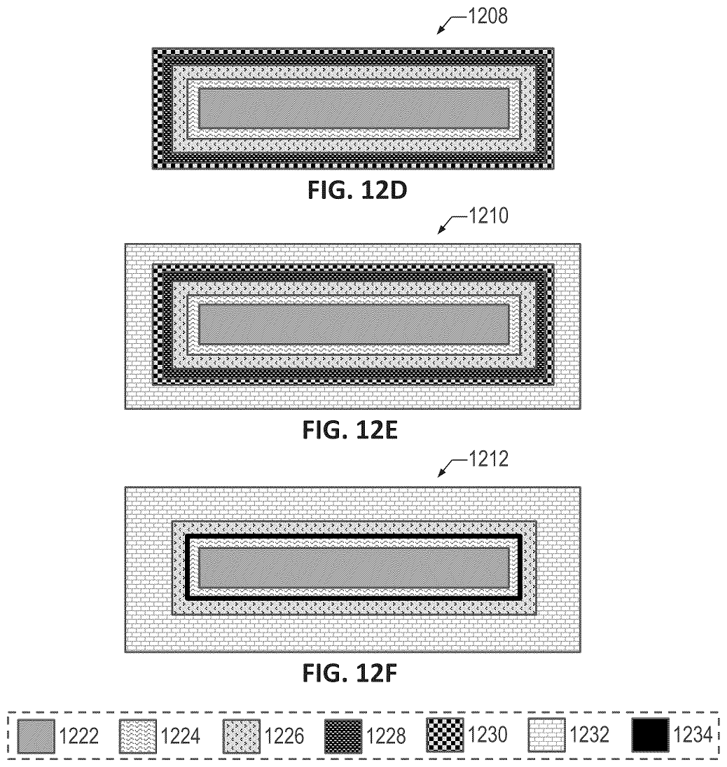

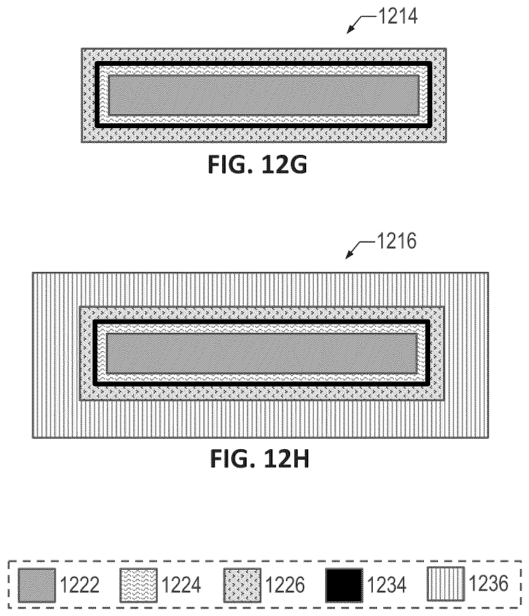

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. To not clutter the drawings, if multiple instances of certain elements are illustrated, only some of the elements may be labeled with a reference sign. A plurality of drawings with the same number and different letters may be referred to without the letters, e.g., FIGS. 12A-12H may be referred to as “FIG. 12.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of transistor gate-channel arrangements with multiple dipole materials as described herein.

A field-effect transistor (FET), e.g., a metal-oxide-semiconductor (MOS) FET (MOSFET), is a three-terminal device that includes source, drain, and gate terminals and uses electric field to control current flowing through the device. A FET typically includes a semiconductor channel material, a source region and a drain region provided in the channel material, and a gate stack that includes at least a gate electrode material and, optionally, may also include a gate insulator, where the gate stack is provided over a portion of the channel material between the source region and the drain region.

Recently, FETs with non-planar architectures, such as FinFETs (also sometimes referred to as “wrap-around gate transistors” or “tri-gate transistors”) and nanowire/nanoribbon/nanosheet transistors (also sometimes referred to as “GAA transistors”), have been extensively explored as alternatives to transistors with planar architectures.

In a FinFET, an elongated semiconductor structure (i.e., an elongated structure that includes a semiconductor material) shaped as a fin extends away from a base (e.g., from a semiconductor substrate or any suitable support structure). A portion of a fin that is closest to the base may be enclosed by an insulator material. Such an insulator material, typically an oxide, is commonly referred to as a “shallow trench isolation” (STI), and the portion of the fin enclosed by the STI is referred to as a “subfin portion” or simply a “subfin.” A gate stack may wrap around an upper portion of the fin (i.e., the portion farthest away from the base). The portion of the fin around which the gate stack wraps is referred to as a “channel” or a “channel portion” of a FinFET. A semiconductor material of the channel portion is commonly referred to as a “channel material” of the transistor. FinFETs are sometimes referred to as “tri-gate transistors” because, in use, such transistors may form conducting channels on three “sides” of the channel portion of the fin. A source region and a drain region are provided in the fin on the opposite sides of the gate stack, forming, respectively, a source and a drain of a FinFET.

Taking a nanoribbon transistor as an example of a GAA transistor, a gate stack may be provided around a portion of an elongated semiconductor structure called “nanoribbon”, forming a gate on all sides of the nanoribbon. The “channel” or the “channel portion” of a nanoribbon transistor is the portion of the nanoribbon around which the gate stack wraps. Such transistors are sometimes referred to as “GAA transistors” because, in use, such transistors may form conducting channels on all “sides” of the channel portion of the nanoribbon. A source region and a drain region are provided in the nanoribbon on each side of the gate stack, forming, respectively, a source and a drain of a nanoribbon transistor. In some settings, the term “nanoribbon” has been used to describe an elongated semiconductor structure that has a substantially rectangular transverse cross-section (i.e., a cross-section in a plane perpendicular to the longitudinal axis of the structure), while the term “nanowire” has been used to describe a similar structure but with a substantially circular or square transverse cross-sections. In the following, a single term “GAA transistor” is used to describe all non-planar transistors where a gate stack wraps around substantially all sides of an elongated semiconductor structure, independent of the shape of the transverse cross-section. Thus, as used herein, the term “GAA transistor” is used to cover transistors with elongated semiconductor structures that have substantially rectangular transverse cross-sections (possibly with rounded corners), transistors with elongated semiconductor structures that have substantially square transverse cross-sections (possibly with rounded corners), transistors with elongated semiconductor structures that have substantially circular or elliptical/oval transverse cross-sections, as well as transistors with elongated semiconductor structures that have any polygonal transverse cross-sections.

As the foregoing illustrates, both FinFETs and GAA transistors are built based on elongated semiconductor structures. A longitudinal axis of such structures may be defined as a line that is the shortest line between a source region and a drain region of a FinFET or a GAA transistor. Typically, such a line extends substantially parallel to a support structure (e.g., a die, a chip, a substrate, a carrier substrate, or a package substrate) on/in which a transistor resides and is one of lines of symmetry for the transistor (at least for the idealized version of the transistor that does not reflect unintended manufacturing variations that may affect the real-life geometry of the transistor). Typically, a length of a fin or a nanowire/nanoribbon/nanosheet (i.e., a dimension measured along the longitudinal axis) is greater than each of a width and a thickness/height of a fin or a nanowire/nanoribbon/nanosheet.

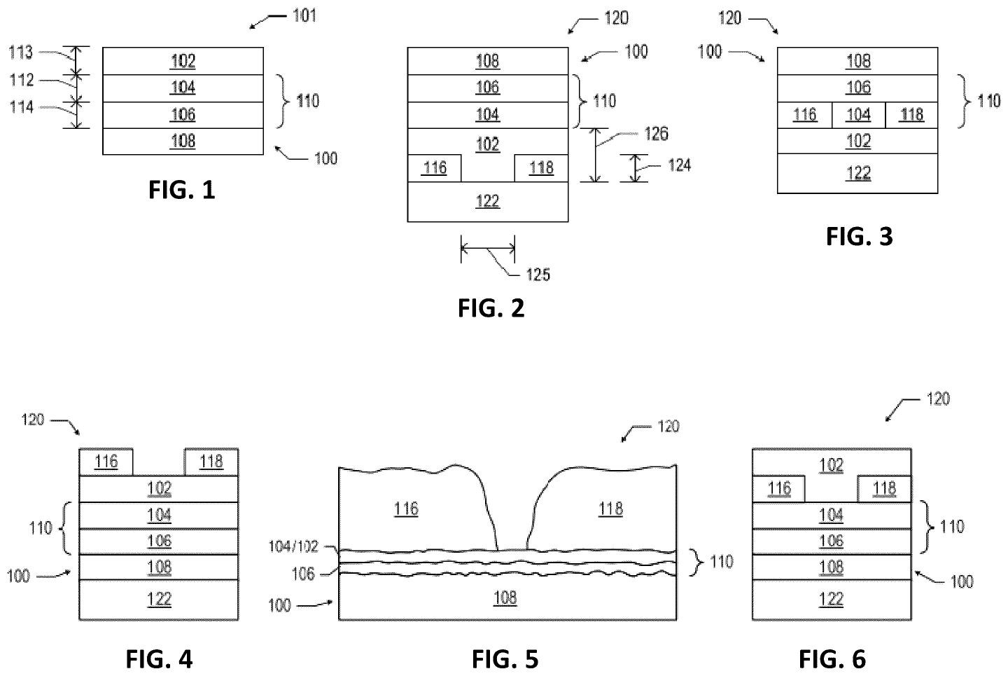

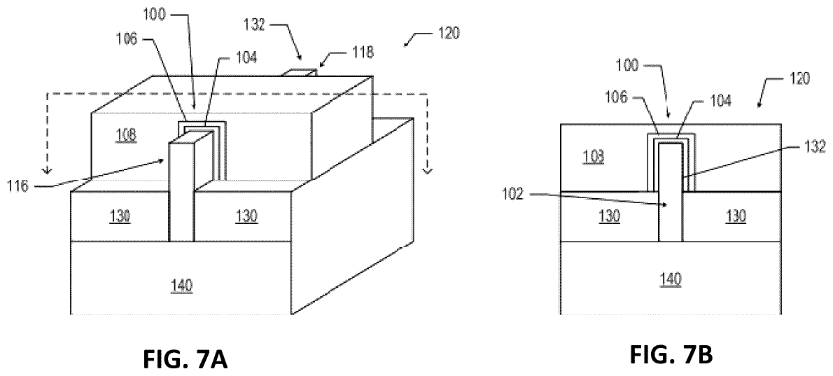

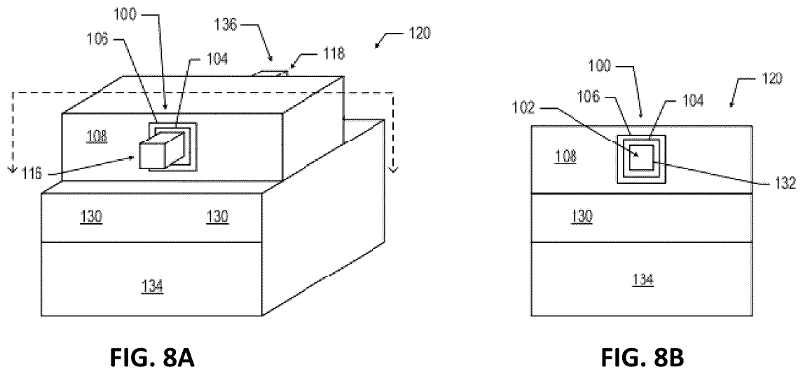

Transistor gate-channel arrangements with multiple dipole materials may be included in transistors of any architecture, such as planar transistors or non-planar transistors, although the advantages may be greater for non-planar transistors because manufacturing processes for fabricating large arrays of such transistors are particularly in need of being less complex while allowing sufficient control of various transistor parameters. FIGS. 1-8 illustrate transistor gate stacks for some example transistors of different types. In particular, FIGS. 1-6 illustrate transistor gate stacks that may be used in planar transistors, while FIGS. 7-8 illustrate non-planar transistors.

FIG. 1 is a cross-sectional side view of a transistor gate-channel arrangement 101 including a channel material 102 and a transistor gate stack 100 (also referred to as a “gate stack 100” herein), in accordance with various embodiments. The transistor gate stack 100 may include a gate electrode material 108, and a multi-dipole gate structure 110 disposed between the gate electrode material 108 and the channel material 102. The multi-dipole gate structure 110 may include an interface layer 104 and a high-k dielectric 106, where the high-k dielectric 106 is disposed between the gate electrode material 108 and the channel material 102, and the interface layer 104 is disposed between the high-k dielectric 106 and the channel material 102. The multi-dipole gate structure 110 may further include two or more dipole materials of different material compositions, e.g., a P-shifter dipole material and an N-shifter dipole material, where atoms of the two or more dipole materials may be distributed throughout the high-k dielectric 106 and/or the interface layer 104 in different manners, depending on the processes used to manufacture the transistor gate stack 100.

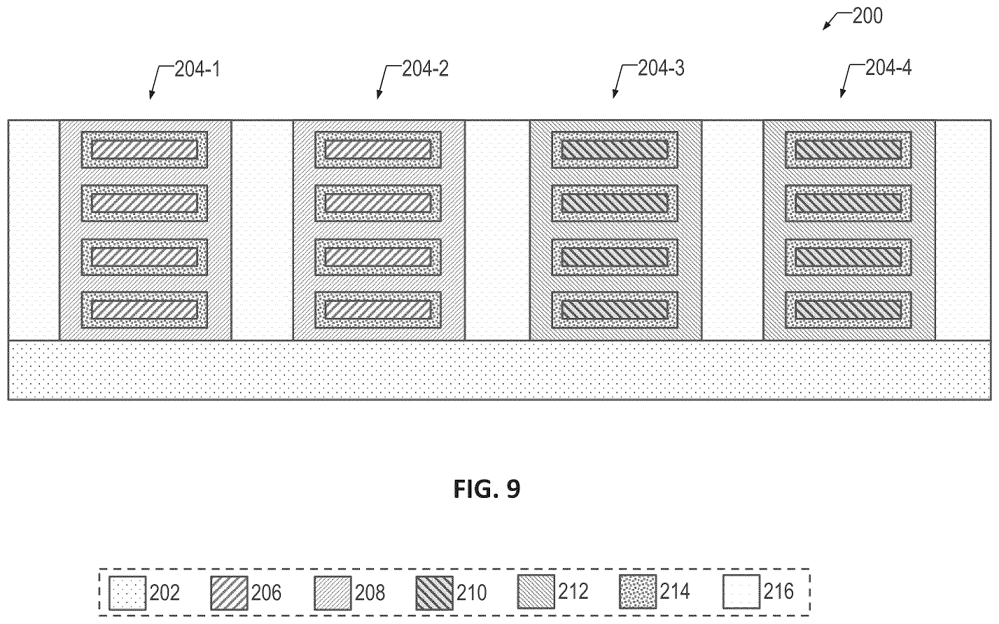

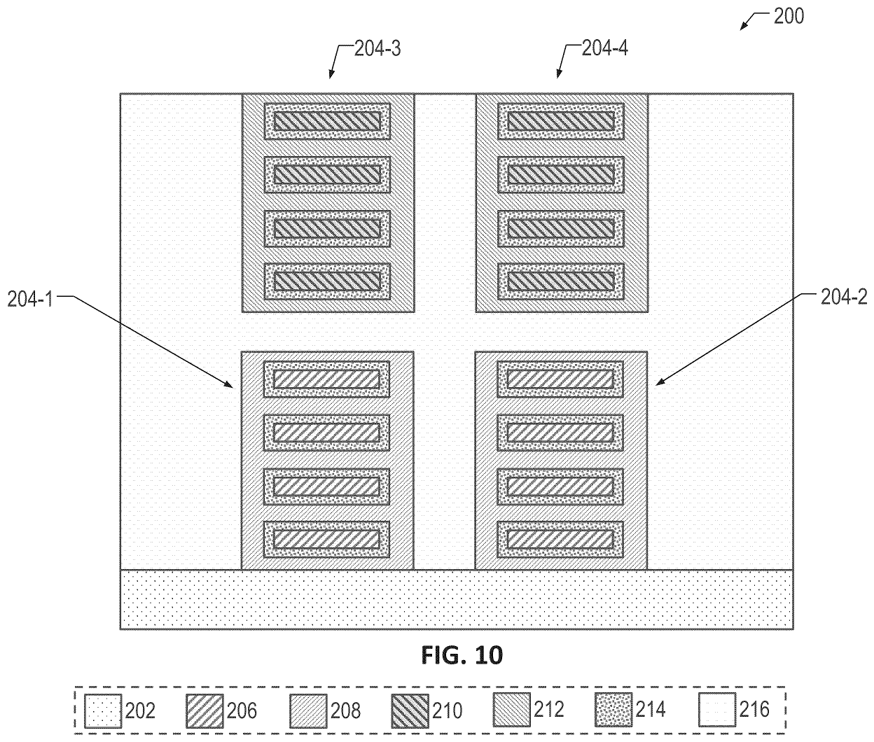

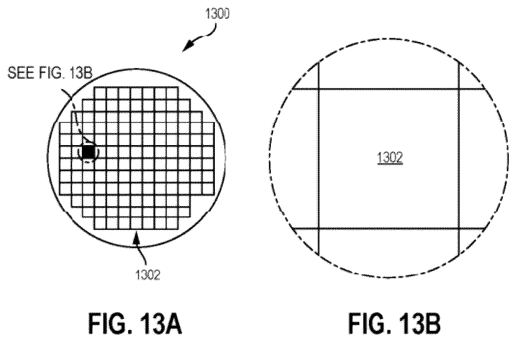

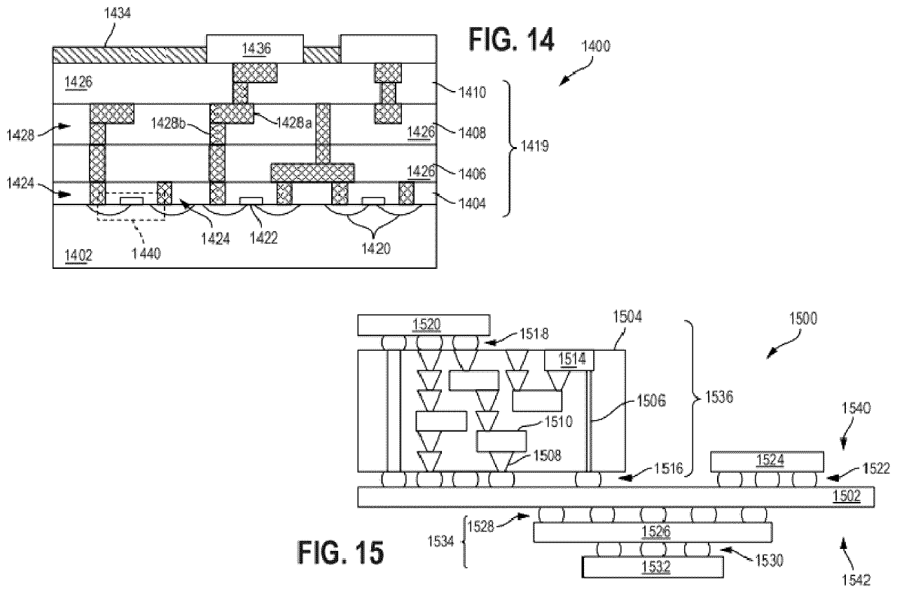

Implementations of the present disclosure may be formed or carried out on any suitable support structure (or, simply, “support”), such as a substrate, a die, a wafer, or a chip. In particular, transistor gate-channel arrangements with multiple dipole materials as described herein may be provided over any suitable support structure. Such a support structure is not shown in FIG. 1 but is shown, e.g., FIGS. 2-4 and FIG. 6 as a substrate 122, in FIGS. 7A and 7B as a base 140, in FIGS. 8A and 8B as a substrate 134, in FIG. 9 and FIG. 10 as a support 202, and in FIG. 14 as a support structure 1402. The support structure may, e.g., be the wafer 1300 of FIG. 13, discussed below, and may be, or be included in, a die, e.g., the singulated die 1302 of FIG. 13, discussed below. The support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the support structure may be formed are described here, any material that may serve as a foundation upon which an IC with one or more transistor gate stacks with multiple dipole materials as described herein may be built falls within the spirit and scope of the present disclosure. As used herein, the term “support structure” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure may provide material “support” in that, e.g., the IC devices/structures described herein are build based on the semiconductor materials of the support structure. However, in some embodiments, the support structure of the IC devices described herein may provide mechanical support.

In general, the channel material 102 may be composed of semiconductor material systems including, for example, N-type or P-type materials systems. In some embodiments, the channel material 102 may include a substantially monocrystalline semiconductor, such as silicon (Si) or germanium (Ge). In some embodiments, the channel material 102 may include a compound semiconductor with a first sub-lattice of at least one element from group III of the periodic table (e.g., Al, Ga, In), and a second sub-lattice of at least one element of group V of the periodic table (e.g., P, As, Sb). In some embodiments, the channel material 102 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 102 may include a combination of semiconductor materials.

For some example N-type transistor embodiments (i.e., for the embodiments where the transistor in which the gate stack 100 is included is an NMOS transistor), the channel material 102 may include a Ill-V material having a relatively high electron mobility, such as, but not limited to InGaAs, InP, InSb, and InAs. For some such embodiments, the channel material 102 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor in which the gate stack 100 is included is a PMOS transistor), the channel material 102 may advantageously be a group IV material having a high hole mobility, such as, but not limited to Ge or a Ge-rich SiGe alloy. For some example embodiments, the channel material 102 may have a Ge content between 0.6 and 0.9, and advantageously may be at least 0.7.

In some embodiments, the channel material 102 may be a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the channel material 102 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc.

As noted above, the channel material 102 may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors. IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

In some embodiments, the transistor in which the gate stack 100 is included may be a thin-film transistor (TFT). A TFT is a special kind of a FET made by depositing a thin film of an active semiconductor material, as well as a dielectric layer (e.g., the multilayer gate insulator 110) and a gate electrode (e.g., the gate electrode material 108), over a support (e.g., a support structure as described above) that may be a non-conducting support. Some such materials may be deposited at relatively low temperatures, which allows depositing them within the thermal budgets imposed on back-end fabrication to avoid damaging the front end components such as the logic devices of an IC device in which the gate stack 100 may be included. At least a portion of the active semiconductor material forms a channel of the TFT. In some such embodiments, the channel material 102 may be deposited as a thin film and may include any of the oxide semiconductor materials described above.

In other embodiments, instead of being deposited at relatively low temperatures as described above with reference to the TFTs, the channel material 102 may be epitaxially grown in what typically involves relatively high-temperature processing. In such embodiments, the channel material 102 may include any of the semiconductor materials described above, including oxide semiconductor materials. In some such embodiments, the channel material 102 may be epitaxially grown directly on a semiconductor layer of a support structure over which the transistor that includes the gate stack 100 will be fabricated, in a process known as “monolithic integration.” In other such embodiments, the channel material 102 may be epitaxially grown on a semiconductor layer of another support structure and then the epitaxially grown layer of the channel material 102 may be transferred, in a process known as a “layer transfer,” to a support structure of which the transistor that includes the gate stack 100 will be fabricated, in which case the latter support structure may but does not have to include a semiconductor layer prior to the layer transfer. Layer transfer advantageously allows forming non-planar transistors, such as FinFETs or GAA transistors, over support structures or in layers that do not include semiconductor materials (e.g., in the back-end of an IC device). Layer transfer also advantageously allows forming transistors of any architecture (e.g., non-planar or planar transistors) without imposing the negative effects of the relatively high-temperature epitaxial growth process on devices that may already be present over a support structure.

The channel material 102 deposited at relatively low temperatures is typically a polycrystalline, polymorphous, or amorphous semiconductor, or any combination thereof. The channel material 102 epitaxially grown is typically a highly crystalline (e.g., monocrystalline, or single-crystalline) material. Therefore, whether the channel material 102 is deposited at relatively low temperatures or epitaxially grown can be identified by inspecting grain size of the active portions of the channel material 102 (e.g., of the portions of the channel material 102 that form channels of transistors). An average grain size of the channel material 102 being between about 0.5 and 1 millimeters (in which case the material may be polycrystalline) or smaller than about 0.5 millimeter (in which case the material may be polymorphous or amorphous) may be indicative of the channel material 102 having been deposited (e.g., in which case the transistors in which such channel material 102 is included are TFTs). On the other hand, an average grain size of the channel material 102 being equal to or greater than about 1 millimeter (in which case the material may be a single-crystal material) may be indicative of the channel material 102 having been epitaxially grown and included in the final device either by monolithic integration or by layer transfer.

The channel material 102 may have a thickness 113. In some embodiments, the thickness 113 may be between about 5 and 75 nanometers, including all values and ranges therein, e.g., between about 5 and 50 nanometers or between about 5 and 30 nanometers.

The gate electrode material 108 may include at least one P-type work function metal or N-type work function metal, depending on whether the transistor gate stack 100 is to be included in a PMOS transistor or an NMOS transistor. For a PMOS transistor, metals that may be used for the gate electrode material 108 may include, but are not limited to, ruthenium, palladium, platinum, cobalt, nickel, and conductive metal oxides (e.g., ruthenium oxide). For an NMOS transistor, metals that may be used for the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of two or more metal layers, where one or more metal layers are work function metal layers and at least one metal layer is a fill metal layer. Further metal layers may be included for other purposes, such as to act as a barrier layer.

The multi-dipole gate structure 110 may include a high-k dielectric 106 and an interface layer 104, arranged in the gate stack 100 so that the interface layer 104 is disposed between the high-k dielectric 106 and the channel material 102. The interface layer 104 may be in contact with the channel material 102, and may provide the interface between the channel material 102 and the remainder of the multi-dipole gate structure 110. In some embodiments, the interface layer 104 may include IGZO. In such embodiments, the interface layer 104 may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). The use of IGZO at the interface between the gate stack 100 and the channel material 102 may achieve one or more of a number of advantages. An IGZO interface may have a relatively small number of interface traps, defects at which carriers are trapped and released that impede performance. A gate stack that includes an IGZO interface may exhibit desirably low gate leakage. When IGZO is used as an interface to a non-IGZO semiconducting oxide channel material (e.g., a thin film oxide semiconductor material having a higher mobility than IGZO), the benefits of the higher mobility channel material may be realized simultaneously with the good gate oxide interface properties provided by the IGZO. As used herein, “low indium content” IGZO may refer to IGZO having more gallium than indium (e.g., with a gallium to indium ratio greater than 1:1), and may also be referred to as “high gallium content” IGZO. Similarly, “low gallium content” IGZO may refer to IGZO having more indium than gallium (e.g., with a gallium to indium ratio less than 1:1), and may also be referred to as “high indium content” IGZO.

In some embodiments, the interface layer 104 may include multiple regions of oxide having different material properties. For example, the interface layer 104 may include low indium content IGZO close to (e.g., in contact with) the high-k dielectric 106, and a high indium content IGZO close to (e.g., in contact with) the channel material 102. High indium content IGZO may provide higher mobility and poorer interface properties relative to low indium content IGZO, while low indium content IGZO may provide a wider band gap, lower gate leakage, and better interface properties, although a lower mobility, relative to high indium content IGZO.

The interface layer 104 may be an amorphous, crystalline, or semi crystalline oxide semiconductor. The ability to deposit the interface layer 104 at temperatures low enough to be compatible with back-end manufacturing processes represents a particular advantage. The interface layer 104 may be deposited on sidewalls or conformably on any desired structure to a precise thickness, allowing the manufacture of transistors having any desired geometry. Additionally, deposition of the interface layer 104 may be compatible with deposition of many materials that may act as the high-k dielectric 106 (e.g., hafnium oxide). The interface layer 104 may have a thickness 112. In some embodiments, the thickness 112 may be between 0.5 nanometers and 5 nanometers (e.g., between 5 Ångströms and 3 nanometers, or between 6 Ångströms and 3 nanometers). When the interface layer 104 borders a channel material 102 different from IGZO, the thickness 112 of the interface layer 104 may be selected to be low enough to limit spillover of carriers, as determined by the application. As noted above, in some embodiments, the channel material 102 may itself be IGZO and the interface layer 104 may be IGZO; in such embodiments, a single layer or region of IGZO may act as both the interface layer 104 and the channel material 102.

The high-k dielectric 106 may include elements such as hafnium, silicon, oxygen, titanium, tantalum, lanthanum, aluminum, zirconium, barium, strontium, yttrium, lead, scandium, niobium, and zinc. Examples of high-k materials that may be used in the high-k dielectric 106 may include, but are not limited to, hafnium oxide, hafnium silicon oxide, lanthanum oxide, zirconium oxide, zirconium silicon oxide, tantalum oxide, titanium oxide, barium strontium titanium oxide, yttrium oxide, aluminum oxide, tantalum oxide, tantalum silicon oxide, lead scandium tantalum oxide, and lead zinc niobate. In some embodiments, an annealing process may be carried out on the high-k dielectric 106 during manufacture of the gate stack 100 to improve the quality of the high-k dielectric 106. The high-k dielectric 106 may have a thickness 114. In some embodiments, the thickness 114 may be between 0.5 nanometers and 3 nanometers (e.g., between 1 and 3 nanometers, or between 1 and 2 nanometers).

In some embodiments, the interface layer 104 may be in contact with the high-k dielectric 106, while in other embodiments, an intermediate material may be disposed between the interface layer 104 and the high-k dielectric 106. In particular, in some embodiments, the interface between the interface layer 104 and the high-k dielectric 106 may be a region where concentration of multiple dipole materials may be the highest and, therefore, it may be considered that an intermediate material that is a combination of multiple dipole materials is disposed between the interface layer 104 and the high-k dielectric 106. More generally, the multilayer gate insulator 110 may include atoms of a first dipole material and atoms of a second dipole material, different from the first dipole material. In some embodiments, the multiple dipole materials may have the highest concentration at the interface between the interface layer 104 and the high-k dielectric 106 and their concentration may decrease away from said interface. In some embodiments, the multiple dipole materials may have greater concentrations in the high-k dielectric 106 than in the interface layer 104. In some embodiments, the multiple dipole materials may be distributed substantially uniformly throughout the high-k dielectric 106 and/or the interface layer 104. In some embodiments, one of the first and second dipole materials may be a P-shifter, while the other one may be an N-shifter. A P-shifter dipole material may include one or more of aluminum, vanadium, niobium, titanium, boron, gallium, molybdenum, chromium, cobalt, tantalum, or tungsten. An N-shifter dipole material may include one or more of lanthanum, molybdenum, strontium, scandium, magnesium, manganese, barium, cerium, erbium, dysprosium, europium, gadolinium, holium, yttrium, lutetium, neodynium, samarium, or terbium. In various embodiments, the atomic percentage of each of at least one P-shifter dipole material and at least one N-shifter dipole material of multiple dipole materials in at least some regions of the multilayer gate insulator 110 (e.g., at the interface between the interface layer 104 and the high-k dielectric 106) may be at least 1%, e.g., between about 1% and 50%, indicating that each of these dipole materials is added deliberately, as opposed to being accidental impurities which are typically in concentration below about 0.1%. Any differences in the material composition of the P-shifter and N-shifter dipole materials that are beyond the unintentional doping and/or impurities levels of about 0.1% of a given one of these different types of dipole materials could be indicative of the method 1100 used to fabricate a transistor with these materials in its gate stack.

The transistor gate stack 100 may be included in any suitable transistor structure. For example, FIGS. 2-6 are cross-sectional side views of example single-gate transistors 120 including a transistor gate stack 100, FIGS. 7A and 7B are perspective and cross-sectional side views, respectively, of an example tri-gate transistor 120 including a transistor gate stack, and FIGS. 8A and 8B are perspective and cross-sectional side views, respectively, of an example GAA transistor 120 including a transistor gate stack, in accordance with various embodiments. The transistors 120 illustrated in FIGS. 2-8 do not represent an exhaustive set of transistor structures in which a gate stack 100 may be included, but that may provide examples of such structures. Although particular arrangements of materials are discussed below with reference to FIGS. 2-8, intermediate materials may be included in the gate stacks 100 of the transistors 120 as discussed above with reference to FIG. 1. Note that FIGS. 2-6 are intended to show relative arrangements of the components therein, and that transistors 120 may include other components that are not illustrated (e.g., electrical contacts to the source region 116 and the drain region 118 to transport current in and out of the transistors 120). Any of the components of the transistors 120 discussed below with reference to FIGS. 2-8 may take the form of any of the embodiments of those components discussed above with reference to FIG. 1. Additionally, although various components of the transistors 120 are illustrated in FIGS. 2-8 as being planar rectangles or formed of rectangular solids, this is simply for ease of illustration, and embodiments of these transistors 120 may be curved, rounded, or otherwise irregularly shaped as dictated by the manufacturing processes used to fabricate the transistors 120.

FIG. 2 depicts a transistor 120 including a transistor gate stack 100 and having a single “top” gate provided by the gate electrode material 108 and the multi-dipole gate structure 110 (which includes the high-k dielectric 106, the interface layer 104, and multiple dipole materials diffused through the high-k dielectric 106 and, possibly, the interface layer 104). The multi-dipole gate structure 110 may be disposed between the gate electrode material 108 and the channel material 102. The multi-dipole gate structure 110 may border the channel material 102; in particular, the interface layer 104 may contact the channel material 102 without any intervening material (and in some embodiments, the interface layer 104 may be the channel material 102). In the embodiment of FIG. 2, the gate stack 100 is shown as disposed on a substrate 122. The substrate 122 may be any structure on which the gate stack 100, or other elements of the transistor 120, is disposed. In some embodiments, the substrate 122 may include a semiconductor, such as silicon. In some embodiments, the substrate 122 may include an insulating layer, such as an oxide isolation layer. For example, in the embodiments of FIGS. 2 and 3, the substrate 122 may include a semiconductor material and an interface layer dielectric (ILD) disposed between the semiconductor material and the source region 116, the channel material 102, and the drain region 118, to electrically isolate the semiconductor material of the substrate 122 from the source region 116, the channel material 102, and the drain region 118 (and thereby mitigate the likelihood that a conductive pathway will form between the source region 116 and the drain region 118 through the substrate 122). Examples of ILDs that may be included in a substrate 122 in some embodiments may include silicon oxide, silicon nitride, aluminum oxide, and/or silicon oxynitride. Any suitable ones of the embodiments of the substrate 122 described with reference to FIG. 2 may be used for the substrates 122 of others of the transistors 102 disclosed herein.

As noted above, the transistor 120 may include a source region 116 and a drain region 118 disposed on the substrate 122, with the channel material 102 disposed between the source region 116 and the drain region 118 so that at least some of the channel material 102 is coplanar with at least some of the source region 116 and the drain region 118. The source region 116 and the drain region 118 may have a thickness 124, and the channel material 102 may have a thickness 126. The thickness 126 may take the form of any of the embodiments of the thickness 113 discussed above with reference to FIG. 1. In some embodiments, the thickness 124 may be less than the thickness 126 (as illustrated in FIG. 2, with the source region 116 and the drain region 118 each disposed between some of the channel material 102 and the substrate 122), while in other embodiments, the thickness 124 may be equal to the thickness 126. In some embodiments, the channel material 102, the interface layer 104, the high-k dielectric 106, and/or the gate electrode material 108 may conform around the source region 116 and/or the drain region 118. The source region 116 and the drain region 118 may be spaced apart by a distance 125 that is the gate length of the transistor 120. In some embodiments, the gate length may be between 10 and 30 nanometers (e.g., between 12 and 28 nanometers, or approximately 25 nanometers).

The source region 116 and the drain region 118 may be formed using any suitable processes known in the art. For example, one or more layers of metal and/or metal alloys may be deposited or otherwise provided to form the source region 116 and the drain region 118, as known for thin film transistors based on semiconductor oxide systems. Any suitable ones of the embodiments of the source region 116 and the drain region 118 described above may be used for any of the source regions 116 and drain regions 118 described herein.

FIG. 3 depicts a transistor 120 including a transistor gate stack 100 and having a single “top” gate provided by the gate electrode material 108 and the multi-dipole gate structure 110 (which includes the high-k dielectric 106 and the interface layer 104). The multi-dipole gate structure 110 may be disposed between the gate electrode material 108 and the channel material 102. The multi-dipole gate structure 110 may border the channel material 102; in particular, the interface layer 104 may contact the channel material 102 without any intervening material (and in some embodiments, the interface layer 104 may be the channel material 102). In the embodiment of FIG. 3, the gate stack 100 is shown as disposed on a substrate 122. The transistor 120 may include a source region 116 and a drain region 118 disposed on the substrate 122, with the interface layer 104 disposed between the source region 116 and the drain region 118 so that at least some of the interface layer 104 is coplanar with at least some of the source region 116 and the drain region 118. As discussed above, in some embodiments, the substrate 122 of FIG. 3 may include a semiconductor material and ILD disposed between the semiconductor material and the source region 116, the channel material 102, and the drain region 118, to electrically isolate the semiconductor material of the substrate 122 from the source region 116, the channel material 102, and the drain region 118. In some embodiments, the interface layer 104, the high-k dielectric 106, and/or the gate electrode material 108 may conform around the source region 116 and/or the drain region 118.

FIG. 4 depicts a transistor 120 including a transistor gate stack 100 and having a single “bottom” gate provided by the gate electrode material 108 and the multi-dipole gate structure 110 (which includes the high-k dielectric 106 and the interface layer 104). The multi-dipole gate structure 110 may be disposed between the gate electrode material 108 and the channel material 102. The multi-dipole gate structure 110 may border the channel material 102; in particular, the interface layer 104 may contact the channel material 102 without any intervening material (and in some embodiments, the interface layer 104 may be the channel material 102). In the embodiment of FIG. 4, the gate stack 100 is shown as disposed on a substrate 122 in an orientation “upside down” to the one illustrated in FIG. 2; that is, the gate electrode material 108 may be disposed between the substrate 122 and the channel material 102. The transistor 120 may include a source region 116 and a drain region 118 disposed on the channel material 102 such that the source region 116 and the drain region 118 are not coplanar with the channel material 102.

FIG. 5 depicts a transistor 120 having the structure of the transistor 120 of FIG. 4. In particular, the transistor 120 of FIG. 5 includes a transistor gate stack 100 and has a single “bottom” gate provided by the gate electrode material 108 and the multi-dipole gate structure 110 (which includes the high-k dielectric 106 and the interface layer 104). In the embodiment of FIG. 5, the interface layer 104 provides the channel material 102, so the channel material 102 is not separately labeled. The transistor 120 of FIG. 5 may also include a substrate 122 (not shown) arranged so that the gate electrode material 108 is disposed between the substrate 122 and the multi-dipole gate structure 110. The transistor 120 may include a source region 116 and a drain region 118 disposed on the channel 102 such that the source region 116 and the drain region 118 are not coplanar with the channel material 102. In the embodiment depicted in FIG. 5, the source region 116 and the drain region 118 may be deposited on the interface layer 104. Any suitable materials may be used to form the transistor 120 of FIG. 5, as discussed above. For example, the gate electrode material 108 may be titanium nitride, the high-k dielectric 106 may be hafnium oxide, and the source region 116 and the drain region 118 may be formed of aluminum. The gate length of the transistor 120 of FIG. 5 may be approximately 25 nanometers.

FIG. 6 depicts a transistor 120 including a transistor gate stack 100 and having a single “bottom” gate provided by the gate electrode material 108 and the multi-dipole gate structure 110 (which includes the high-k dielectric 106 and the interface layer 104). The multi-dipole gate structure 110 may be disposed between the gate electrode material 108 and the channel material 102. The multi-dipole gate structure 110 may border the channel material 102; in particular, the interface layer 104 may contact the channel material 102 without any intervening material (and in some embodiments, the interface layer 104 may be the channel material 102). In the embodiment of FIG. 6, the gate stack 100 is shown as disposed on a substrate 122 in an orientation “upside down” to the one illustrated in FIG. 2; that is, the gate electrode material 108 may be disposed between the substrate 122 and the channel material 102. The transistor 120 may include a source region 116 and a drain region 118 disposed on the channel material 102 such that at least some of the source region 116 and at least some of the drain region 118 are coplanar with at least some of the channel material 102. In some embodiments, the source region 116 and the drain region 118 may each be disposed between some of the channel material 102 and the substrate 122, as illustrated in FIG. 6, while in other embodiments, the channel material 102 may not extend “above” the source region 116 or the drain region 118. In some embodiments, the channel material 102 may conform around the source region 116 and/or the drain region 118.

FIGS. 7A and 7B are perspective and cross-sectional side views, respectively, of an example tri-gate transistor 120 including a transistor gate stack 100, in accordance with various embodiments. The transistor 120 of FIGS. 7A and 7B may include a channel material 102, and a gate stack 100 including a gate electrode material 108 and a multi-dipole gate structure 110 that includes a high-k dielectric 106, an interface layer 104, and two or more dipole materials of different material compositions. The interface layer 104 may be disposed between the high-k dielectric 106 and the channel material 102 (e.g., the interface layer 104 may be in contact with the channel material 102). In the tri-gate transistor 120 illustrated in FIGS. 7A and 7B, a fin 132 formed of a semiconductor material may extend from a base 140 of the semiconductor material. An oxide material 130 may be disposed on either side of the fin 132. In some embodiments, the oxide material 130 may include any of the materials discussed herein with reference to the high-k dielectric 106. In other embodiments, the oxide material 130 may include a low-k dielectric.

The gate stack 100 may wrap around the fin 132 as shown, with the channel material 102 corresponding to the portion of the fin 132 wrapped by the gate stack 100. In particular, the interface layer 104 may wrap around the channel material 102 of the fin 132, the high-k dielectric 106 may wrap around the interface layer 104, and the gate electrode material 108 may wrap around the high-k dielectric 106. The fin 132 may include a source region 116 and a drain region 118 on either side of the gate stack 100, as shown. The composition of the channel material 102, the source region 116, and a drain region 118 may take the form of any of the embodiments disclosed herein, or known in the art. Although the fin 132 illustrated in FIGS. 7A and 7B is shown as having a rectangular cross-section, the fin 132 may instead have a cross-section that is rounded or sloped at the “top” of the fin 132, and the gate stack 100 may conform to this rounded or sloped fin 132. In use, the tri-gate transistor 120 may form conducting channels on three “sides” of the fin 132, potentially improving performance relative to single-gate transistors (which may form conducting channels on one “side” of the channel material 102) and double-gate transistors (which may form conducting channels on two “sides” of the channel material 102).

FIGS. 8A and 8B are perspective and cross-sectional side views, respectively, of an example GAA transistor 120 including a transistor gate stack 100, in accordance with various embodiments. The transistor 120 of FIGS. 8A and 8B may include a channel material 102, and a gate stack 100 including a gate electrode material 108 and a multi-dipole gate structure 110 that includes a high-k dielectric 106, an interface layer 104, and two or more dipole materials of different material compositions. The interface layer 104 may be disposed between the high-k dielectric 106 and the channel material 102 (e.g., the interface layer 104 may be in contact with the channel material 102). In the GAA transistor 120 illustrated in FIGS. 8A and 8B, a wire 136 formed of a semiconductor material may extend above a substrate 134 and a layer of oxide material 130. The wire 136 may take the form of a nanowire or nanoribbon, for example. The gate stack 100 may wrap entirely or almost entirely around the wire 136, as shown, with the channel material 102 corresponding to the portion of the wire 136 wrapped by the gate stack 100. In particular, the interface layer 104 may wrap around the channel material 102 of the fin 132, the high-k dielectric 106 may wrap around the interface layer 104, and the gate electrode material 108 may wrap around the high-k dielectric 106. In some embodiments, the gate stack 100 may fully encircle the wire 136. The wire 136 may include a source region 116 and a drain region 118 on either side of the gate stack 100, as shown. The composition of the channel material 102, the source region 116, and a drain region 118 may take the form of any of the embodiments disclosed herein, or known in the art. Although the wire 136 illustrated in FIGS. 8A and 8B is shown as having a rectangular cross-section, the wire 136 may instead have a cross-section that is rounded or otherwise irregularly shaped, and the gate stack 100 may conform to the shape of the wire 136. In use, the tri-gate transistor 120 may form conducting channels on more than three “sides” of the wire 136, potentially improving performance relative to tri-gate transistors. Although FIGS. 8A and 8B depict an embodiment in which the longitudinal axis of the wire 136 runs substantially parallel to a plane of the oxide material 130 (and a plane of the substrate 134), this need not be the case; in other embodiments, for example, the wire 136 may be oriented “vertically” so as to be perpendicular to a plane of the oxide 130 (or plane of the substrate 134).

FIGS. 9-10 are cross-sectional side views of example IC devices 200 with N-type and P-type GAA transistors with gate stacks with multiple dipole materials, in accordance with various embodiments. In FIGS. 9-10, as well as in FIGS. 12A-12H, some of the elements shown in the drawings are referred in the present description with reference numerals illustrated in these drawings with different patterns, with a legend showing the correspondence between the reference numerals and patterns being provided at the bottom of each drawing page of FIGS. 9-10 and FIGS. 12A-12H. Furthermore, although a certain number of a given element may be illustrated in FIGS. 9-10 (e.g., four nanoribbons in each stack and four stacks of nanoribbons), this is also simply for ease of illustration, and more, or less, than that number may be included in IC structures/devices according to various embodiments of the present disclosure.

FIGS. 9-10 illustrate an IC device 200 that includes a support 202 and a plurality of stacks 204 of nanoribbons 206 provided over the support 202. Stacks 204-1 and 204-2 may be N-type stacks (i.e., stacks based on which NMOS transistors are formed), while stacks 204-3 and 204-3 may be P-type stacks (i.e., stacks based on which PMOS transistors are formed). As shown in FIGS. 9-10, the stacks 204-1 and 204-2 may include a channel material 206 and a gate electrode material 208, while the stacks 204-3 and 204-4 may include a channel material 210 and a gate electrode material 212. In some embodiments, the channel materials 206 and 210 may have different material compositions. In other embodiments, material compositions of the channel materials 206 and 210 may be the same. The channel materials 206 and 210 may include any of the materials described with reference to the channel material 102. Material compositions of the gate electrode materials 208 and 212 may be different. The gate electrode materials 208 and 212 may include any of the materials described with reference to the gate electrode material 108. FIGS. 9-10 further illustrate gate stacks 214, where any of the gate stacks 214 may include a multi-dipole gate structure 110 as described above. In some embodiments, different ones of the gate stacks 214 that include the multi-dipole gate structure 110 may include different dipole materials. In some embodiments, some of the gate stacks 214 may include only one dipole material or different dipole materials but of only one type (i.e., only N-shifters or only P-shifters). In some embodiments, some of the gate stacks 214 may not include any dipole materials. FIGS. 9-10 further illustrate an insulator material 216 that may be used to provide electrical insulation between transistors of different stacks 204. Although not specifically shown in FIGS. 9-10, interconnects (e.g., trenches and/or vias as described below with reference to interconnect structures 1428) may extend though the insulator material 216 to electrically connect various elements of the IC device 200, e.g., to electrically connect select terminals of one or more transistors of the stacks 204-1 and/or 204-2 and select terminals of one or more transistors of the stacks 204-3 and/or 204-4 to form logic circuits as known in the art.

FIG. 9 illustrates an embodiment of the IC device 200 where different stacks 204 are provided in substantially the same layer above the support 202, i.e., over different portions of the support 202. On the other hand, the IC device 200 shown in FIG. 10 is similar to that of FIG. 9, but where the stacks 204-3 and 204-4 are stacked above the stacks 204-1 and/or 204-2. In various other embodiments, other arrangements of N-type stacks and P-type stacks are possible, all of which being within the scope of the present disclosure.

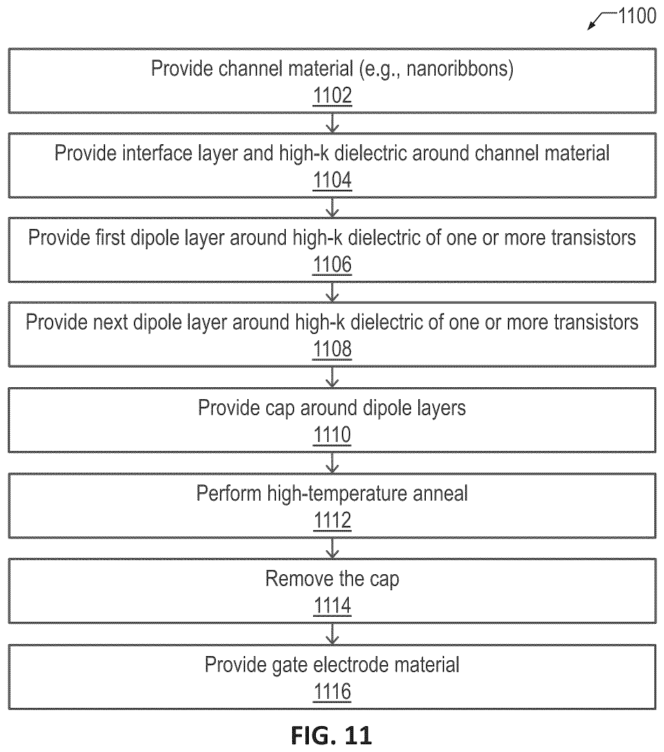

The transistor gate stacks 100 disclosed herein may be manufactured using any suitable techniques. For example, FIG. 11 is a flow diagram of an example method 1100 of manufacturing a transistor gate stack, in accordance with various embodiments. Although the operations of the method 1100 are illustrated once each and in a particular order, the operations may be performed in any suitable order and repeated as desired. For example, one or more operations may be performed in parallel to manufacture multiple transistor gate stacks substantially simultaneously. In another example, the operations may be performed in a different order to reflect the structure of a transistor in which the transistor gate stack will be included. FIGS. 12A-12H illustrates cross-sectional side views of example transistor gate-channel arrangements after various processes of the method of FIG. 11, in accordance with various embodiments.

Although the operations of the manufacturing method illustrated in FIG. 11 are illustrated once each and in a particular order, the operations may be performed in any suitable order and repeated as desired. For example, the operations may be performed in a different order to reflect the structure of an IC device in which a transistor gate stack will be included. In addition, the example manufacturing method illustrated in FIG. 11 may include other operations not specifically shown in the drawings, such as various cleaning or planarization operations as known in the art. For example, in some embodiments, a support structure, as well as layers of various other materials subsequently deposited thereon, may be cleaned prior to, after, or during any of the processes of the manufacturing method illustrated in FIG. 11, e.g., to remove oxides, surface-bound organic and metallic contaminants, as well as subsurface contamination. In some embodiments, cleaning may be carried out using, e.g., a chemical solution (such as peroxide), and/or ultraviolet (UV) radiation combined with ozone, and/or oxidizing the surface (e.g., using thermal oxidation) then removing the oxide (e.g., using hydrofluoric acid (HF)). In another example, the arrangements/devices described herein may be planarized prior to, after, or during any of the processes of the manufacturing method illustrated in FIG. 11 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

At 1102, a channel material may be provided. An IC structure 1202, depicted in FIG. 12A, illustrates an example result of the process 1102. As shown in FIG. 12A, the IC structure 1202 may include a channel material 1222 formed as a nanoribbon, and subsequent drawings of FIG. 12 continue with the example of a nanoribbon, but, in general, the channel material 1222 provided at 1102 may take the form of any of the embodiments of the channel material 102 disclosed herein, e.g., any of the embodiments discussed herein with reference to a transistor 120. The channel material 1222 may be provided at 1102 using any suitable deposition and patterning technique known in the art.

At 1104, interface layer and high-k dielectric may be provided. An IC structure 1204, depicted in FIG. 12B, illustrates an example result of the process 1104. As shown in FIG. 12B, the IC structure 1204 may include an interface layer 1224 adjacent to (e.g., wrapping around) the channel material 1222, and further include a high-k dielectric 1226 adjacent to (e.g., wrapping around) the interface layer 1224. The interface layer 1224 and the high-k dielectric 1226 provided at 1104 may take the form of any of the embodiments of, respectively, the interface layer 104 and the high-k dielectric 106 disclosed herein, e.g., any of the embodiments discussed herein with reference to a transistor 120. The interface layer 1224 and the high-k dielectric 1226 may be provided at 1104 using any suitable deposition and patterning technique known in the art. In some embodiments, the interface layer 1224 may be formed using a low-temperature deposition process, such as physical vapor deposition (PVD) (e.g., sputtering), atomic layer deposition (ALD), or chemical vapor deposition (CVD). In some embodiments where the interface layer 1224 is an oxide, the interface layer 1224 may be grown by thermal oxidation or chemical oxidation. In some embodiments where the interface layer 1224 is an oxynitride (e.g., SiON), the interface layer 1224 may be formed by a nitridation process on top of an oxide (e.g., on top of SiO), where a nitridation process may include thermal nitridation or plasma nitridation performed on top of the interface layer 1224 and/or on top of the high-k dielectric 1226.

At 1106, a layer of a first dipole material may be provided over the high-k dielectric of one or more future transistors that will be based on the channel material provided at 1102. An IC structure 1206, depicted in FIG. 12C, illustrates an example result of the process 1106. As shown in FIG. 12C, the IC structure 1206 may include a first dipole material 1228 adjacent to (e.g., wrapping around) the high-k dielectric 1226. The first dipole material 1228 provided at 1106 may take the form of any of the embodiments of one of the P-shifters or N-shifters described herein, e.g., any of the embodiments discussed herein with reference to the multi-dipole gate structure 110. The first dipole material 1228 may be provided at 1106 using any suitable deposition and patterning technique known in the art. For example, the first dipole material 1228 may be deposited using a conformal deposition technique such as ALD or CVD, where patterning may involve, e.g., using masks to only deposit the first dipole material 1228 for the gate stacks of some select transistors. Some of the future transistors built based on the channel material 1222 provided at 1102 may not have the first dipole material 1228 in their gate stacks. At 1106, the first dipole material 1228 of a certain thickness may be deposited. If larger thicknesses of the first dipole material 1228 are desired for the gate stacks of some transistors, process 1106 may be repeated to deposit additional layers of the first dipole material 1228 around the first (or any previous) layer of the first dipole material 1228. In some embodiments, a thin capping layer may be deposited on top of the first dipole material 1228. The capping layer may include metals such as copper, aluminum, or tungsten, and may have a thickness of less than about 3 nanometers.

At 1108, a layer of a next (e.g., second) dipole material may be provided over the previous dipole material, e.g., over the first dipole material provided at 1106. An IC structure 1208, depicted in FIG. 12D, illustrates an example result of the process 1108. As shown in FIG. 12D, the IC structure 1208 may include a second dipole material 1230 adjacent to (e.g., wrapping around) the first dipole material 1228. The second dipole material 1230 provided at 1108 may take the form of any of the embodiments of one of the P-shifters or N-shifters described herein, e.g., any of the embodiments discussed herein with reference to the multi-dipole gate structure 110. The second dipole material 1230 may be provided at 1108 using any suitable deposition and patterning technique known in the art. For example, the second dipole material 1230 may be deposited using a conformal deposition technique such as ALD or CVD, where patterning may involve, e.g., using masks to only deposit the second dipole material 1230 for the gate stacks of some select transistors. In particular, for at least some of the transistors built based on the channel material 1222 provided at 1102, one of the first dipole material 1228 and the second dipole material 1230 may be a P-shifter while the other one may be an N-shifter. Some of the future transistors built based on the channel material 1222 provided at 1102 may not have the second dipole material 1230 in their gate stacks. Still some other of the future transistors built based on the channel material 1222 provided at 1102 may have the second dipole material 1230 in their gate stacks, but not the first dipole material 1228, or vice versa. At 1108, the second dipole material 1230 of a certain thickness may be deposited. If larger thicknesses of the second dipole material 1230 are desired for the gate stacks of some transistors, process 1108 may be repeated to deposit additional layers of the second dipole material 1230 around the first (or any previous) layer of the second dipole material 1230. In some embodiments, a thin capping layer may be deposited on top of the second dipole material 1230. The capping layer may include metals such as copper, aluminum, or tungsten, and may have a thickness of less than about 3 nanometers. Although not specifically shown in FIG. 11, the method 1100 may include additional processes similar to the process 1108 where different further dipole materials may be deposited.

At 1110, the layers of the dipole materials provided at 1106 and 1108 may be enclosed with a cap. An IC structure 1210, depicted in FIG. 12E, illustrates an example result of the process 1110. As shown in FIG. 12E, the IC structure 1210 may include a cap 1232 adjacent to (e.g., wrapping around) the second dipole material 1230. The cap 1232 may include any suitable material that could act as a hermetic sealant and/or an oxygen diffusion barrier, such as a material that includes titanium and nitrogen (e.g., TiN), possibly in combination with another material such as amorphous silicon. The cap 1232 may be provided at 1110 using any suitable deposition and patterning technique known in the art, such as ALD, CVD, or PVD.

At 1112, a high-temperature anneal may be performed to drive the atoms of the dipole materials deposited at 1106 and 1108 into the high-k dielectric provided at 1104, and, possibly, into the interface layer provided at 1104. The anneal of 1112 may involve, e.g., heating the IC structure 1210 to temperatures above about 1000 degrees Celsius for a duration of time. An IC structure 1212, depicted in FIG. 12F, illustrates an example result of the process 1112. As shown in FIG. 12F, the IC structure 1212 may include a layer 1234 of the multiple dipole materials at the interface between the interface layer 1224 and the high-k dielectric 1226, however this illustration is purely schematic to show that, in some embodiments, concentration of the multiple dipole materials may be highest at the interface of the interface layer 1224 and the high-k dielectric 1226. In some embodiments, at least some of the atoms of the dipole materials deposited at 1106 and 1108 may be present within the high-k dielectric 1226 and/or at least some of the atoms of the dipole materials deposited at 1106 and 1108 may be present within the interface layer 1224. For example, concentration of the multiple dipole materials in the high-k dielectric 1226 may gradually decrease in a direction away from the interface between the interface layer 1224 and the high-k dielectric 1226. In some embodiments, concentration of the multiple dipole materials in the interface layer 1224 may gradually decrease in a direction away from the interface between the interface layer 1224 and the high-k dielectric 1226. Although not specifically shown in FIG. 12F, in some embodiments, at least some of the first dipole material 1228 and/or the second dipole material 1230 may remain around the high-k dielectric 1226 as they were originally deposited. The amount and the pattern of the diffusion undergone by the first dipole material 1228 and/or the second dipole material 1230 during the anneal of 1112 would depend on the temperature and the duration of the anneal, the material compositions of the first dipole material 1228 and/or the second dipole material 1230, the material compositions of the interface layer 1224 and/or the high-k dielectric 1226, and so on. Together, the interface layer 1224, the high-k dielectric 1226, and diffused dipoles of the first and second dipole materials 1228 and 1230 (e.g., forming the layer 1234) provide an example of the multi-dipole gate structure 110 as described herein.

At 1114, the cap provided at 1110 may be removed. An IC structure 1214, depicted in FIG. 12G, illustrates an example result of the process 1114. As shown in FIG. 12G, the IC structure 1214 may be substantially as the IC structure 1212 but without the cap 1232. The cap 1232 may be removed at 1114 using any suitable technique known in the art, such as dry or wet etching. In some embodiments, some dipole material(s) may still be present on top of the high-k dielectric 1226 after the anneal, and, in such embodiments, 1114 may further include removing the remaining dipole material(s), e.g., using wet etching.

At 1116, a gate electrode material may be provided. An IC structure 1216, depicted in FIG. 12H, illustrates an example result of the process 1116. As shown in FIG. 12H, the IC structure 1216 may include a gate electrode material 1236 adjacent to (e.g., wrapping around) the high-k dielectric 1226. The gate electrode material 1236 provided at 1116 may take the form of any of the embodiments of the gate electrode material 108 disclosed herein, e.g., any of the embodiments discussed herein with reference to a transistor 120. The gate electrode material 1236 may be provided at 1116 using any suitable deposition and patterning technique known in the art. Together, the interface layer 1224, the high-k dielectric 1226, diffused dipoles of the first and second dipole materials 1228 and 1230 (e.g., forming the layer 1234), and the gate electrode material 1236 provide an example of the transistor gate stack 100 as described herein. Together, the interface layer 1224, the high-k dielectric 1226, diffused dipoles of the first and second dipole materials 1228 and 1230 (e.g., forming the layer 1234), the gate electrode material 1236, and the channel material 1222 provide an example of the transistor gate-channel arrangement 101 as described herein.

The method 1100 may further include other manufacturing operations related to fabrication of other components of a transistor 120. For example, the method 1100 may include providing a source region and a drain region (e.g., in accordance with any suitable ones of the embodiments discussed above). In another example, the method 1100 may include providing a source contact/electrode and a drain contact/electrode.

Transistors with transistor gate stacks with multiple dipole materials described herein (e.g., as described with reference to FIGS. 1-12) may be used to implement any suitable components. For example, in various embodiments, transistors described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC structures/devices with transistor gate stacks with multiple dipole materials disclosed herein may be included in any suitable electronic device. FIGS. 13-16 illustrate various examples of apparatuses that may include one or more transistor gate stacks with multiple dipole materials disclosed herein.

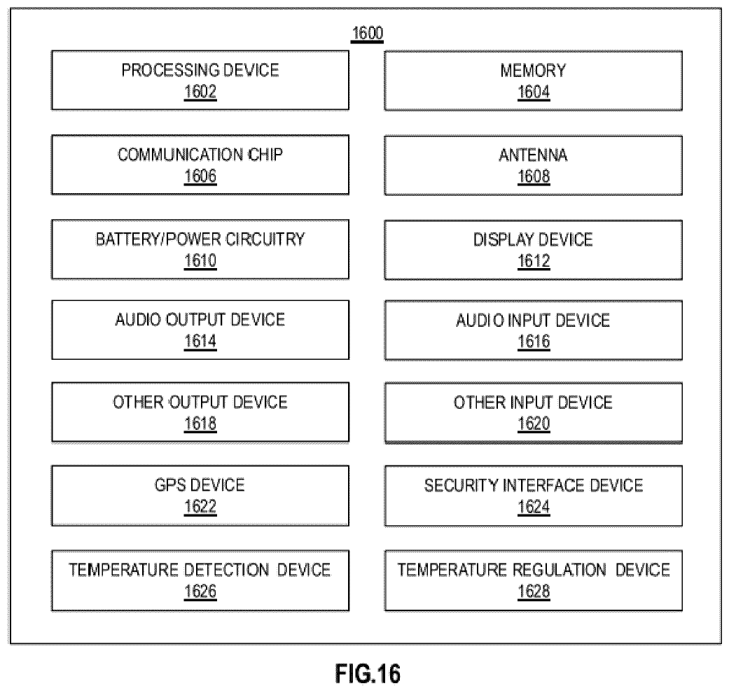

FIGS. 13A and 13B are top views of a wafer 1300 and dies 1302 that may include one or more transistor gate-channel arrangements with multiple dipole materials in accordance with any of the embodiments disclosed herein. The wafer 1300 may be composed of semiconductor material and may include one or more dies 1302 having IC structures formed on a surface of the wafer 1300. Each of the dies 1302 may be a repeating unit of a semiconductor product that includes any suitable IC (e.g., ICs including one or more transistors 120 that include one or more gate stacks 100). After the fabrication of the semiconductor product is complete (e.g., after manufacture of a gate stack 100 in a transistor 120), the wafer 1300 may undergo a singulation process in which each of the dies 1302 is separated from one another to provide discrete “chips” of the semiconductor product. In particular, devices that include a transistor gate stack as disclosed herein may take the form of the wafer 1300 (e.g., not singulated) or the form of the die 1302 (e.g., singulated). The die 1302 may include one or more transistors (e.g., one or more of the transistors 1440 of FIG. 14, discussed below, which may take the form of any of the transistors 120) and/or supporting circuitry to route electrical signals to the transistors, as well as any other IC components. In some embodiments, the wafer 1300 or the die 1302 may include a memory device (e.g., a static random-access memory (SRAM) device), a logic device (e.g., an AND, OR, NAND, or NOR gate), or any other suitable circuit element. Multiple ones of these devices may be combined on a single die 1302. For example, a memory array formed by multiple memory devices may be formed on a same die 1302 as a processing device (e.g., the processing device 1602 of FIG. 16) or other logic that is configured to store information in the memory devices or execute instructions stored in the memory array.

FIG. 14 is a cross-sectional side view of an IC device 1400 that may include one or more transistor gate-channel arrangements with multiple dipole materials in accordance with any of the embodiments disclosed herein. The IC device 1400 may be formed on a support structure 1402 (e.g., the wafer 1300 of FIG. 13A) and may be included in a die (e.g., the die 1302 of FIG. 13B). The support structure 1402 may be a semiconductor substrate composed of semiconductor material systems including, for example, N-type or P-type materials systems. The support structure 1402 may include, for example, a crystalline substrate formed using a bulk silicon or a SOI substructure. In some embodiments, the semiconductor support structure 1402 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the support structure 1402. Although a few examples of materials from which the support structure 1402 may be formed are described here, any material that may serve as a foundation for an IC device 1400 may be used. The support structure 1402 may be part of a singulated die (e.g., the dies 1302 of FIG. 13B) or a wafer (e.g., the wafer 1300 of FIG. 13A).

The IC device 1400 may include one or more device layers 1404 disposed on the support structure 1402. The device layer 1404 may include features of one or more transistors 1440 (e.g., metal-oxide-semiconductor field-effect transistors (MOSFETs)) formed on the support structure 1402. The device layer 1404 may include, for example, one or more source and/or drain (S/D) regions 1420, a gate 1422 to control current flow in the transistors 1440 between the S/D regions 1420, and one or more S/D contacts 1424 to route electrical signals to/from the S/D regions 1420. The transistors 1440 may include additional features not depicted for the sake of clarity, such as device isolation regions, gate contacts, and the like. The transistors 1440 are not limited to the type and configuration depicted in FIG. 14 and may include a wide variety of other types and configurations such as, for example, planar transistors, non-planar transistors, or a combination of both. Non-planar transistors may include FinFET transistors, such as double-gate transistors or FinFETs (e.g., as described with reference to FIGS. 7A and 7B), and wrap-around or GAA transistors, such as nanoribbon and nanowire transistors (e.g., as described with reference to FIGS. 8A and 8B). In particular, one or more of the transistors 1440 may include one or more transistor gate stacks 100 in accordance with any of the embodiments disclosed herein. For example, a transistor 1440 may take the form of any of the transistors 120 disclosed herein (e.g., any of the single-gate transistors discussed herein with reference to FIGS. 2-6, any of the FinFETs discussed herein with reference to FIGS. 7A and 7B, and any of the GAA transistors discussed herein with reference to FIGS. 8A and 8B). The S/D regions 1420 may include the source region 116 and the drain region 118. Transistors 120 including the gate stack 100 may be particularly advantageous when used in the metal layers of a microprocessor device for analog circuitry, logic circuitry, or memory circuitry, and may be formed along with existing complementary MOS (CMOS) processes.

Each transistor 1440 may include a gate 1422 formed of at least two layers, a gate insulator layer and a gate electrode layer. The gate electrode layer may take the form of any of the embodiments of the gate electrode material 108 disclosed herein. In embodiments in which a transistor 1440 includes one or more transistor gate stacks 100, the gate insulator layer may take the form of any of the embodiments of the multi-dipole gate structure 110 disclosed herein.

In some embodiments, when viewed as a cross-section of the transistor 1440 along the source-channel-drain direction, the gate electrode may consist of a U-shaped structure that includes a bottom portion substantially parallel to the surface of the substrate and two sidewall portions that are substantially perpendicular to the top surface of the substrate (e.g., as discussed above with reference to the FinFET 120 of FIGS. 7A and 7B). In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers. In some embodiments, the gate electrode may consist of a V-shaped structure (e.g., when the fin 132 does not have a “flat” upper surface, but instead has a rounded peak).

In some embodiments, a pair of sidewall spacers may be formed on opposing sides of the gate stack to bracket the gate stack. The sidewall spacers may be formed from a material such as silicon nitride, silicon oxide, silicon carbide, silicon nitride doped with carbon, and silicon oxynitride. Processes for forming sidewall spacers are well-known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1420 may be formed within the support structure 1402 adjacent to the gate 1422 of each transistor 1440. The S/D regions 1420 may take the form of any of the embodiments of the source region 116 and the drain region 118 discussed above with reference to the transistors 120. In other embodiments, the S/D regions 1420 may be formed using any suitable processes known in the art. For example, the S/D regions 1420 may be formed using either an implantation/diffusion process or a deposition process. In the former process, dopants such as boron, aluminum, antimony, phosphorous, or arsenic may be ion-implanted into the support structure 1402 to form the S/D regions 1420. An annealing process that activates the dopants and causes them to diffuse farther into the support structure 1402 may follow the ion implantation process. In the latter process, an epitaxial deposition process may provide material that is used to fabricate the S/D regions 1420. In some implementations, the S/D regions 1420 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1420 may be formed using one or more alternate semiconductor materials such as germanium or a group III-V material or alloy. In further embodiments, one or more layers of metal and/or metal alloys may be used to form the S/D regions 1420 (e.g., as discussed above with reference to the source region 116 and the drain region 118). In some embodiments, an etch process may be performed before the epitaxial deposition to create recesses in the support structure 1402 in which the material for the S/D regions 1420 is deposited.

Electrical signals, such as power and/or input/output (I/O) signals, may be routed to and/or from the transistors 1440 of the device layer 1404 through one or more interconnect layers disposed on the device layer 1404 (illustrated in FIG. 14 as interconnect layers 1406-1410). For example, electrically conductive features of the device layer 1404 (e.g., the gate 1422 and the S/D contacts 1424) may be electrically coupled with the interconnect structures 1428 of the interconnect layers 1406-1410. The one or more interconnect layers 1406-1410 may form an interlayer dielectric (ILD) stack 1419 of the IC device 1400.

The interconnect structures 1428 may be arranged within the interconnect layers 1406-1410 to route electrical signals according to a wide variety of designs (in particular, the arrangement is not limited to the configuration of interconnect structures 1428 depicted in FIG. 14). Although a particular number of interconnect layers 1406-1410 is depicted in FIG. 14, embodiments of the present disclosure include IC devices having more or fewer interconnect layers than depicted.

In some embodiments, the interconnect structures 1428 may include trench structures 1428a (sometimes referred to as “lines”) and/or via structures 1428b (sometimes referred to as “holes”) filled with an electrically conductive material such as a metal. The trench structures 1428a may be arranged to route electrical signals in a direction of a plane that is substantially parallel with a surface of the support structure 1402 upon which the device layer 1404 is formed. For example, the trench structures 1428a may route electrical signals in a direction in and out of the page from the perspective of FIG. 14. The via structures 1428b may be arranged to route electrical signals in a direction of a plane that is substantially perpendicular to the surface of the support structure 1402 upon which the device layer 1404 is formed. In some embodiments, the via structures 1428b may electrically couple trench structures 1428a of different interconnect layers 1406-1410 together.

The interconnect layers 1406-1410 may include a dielectric material 1426 disposed between the interconnect structures 1428, as shown in FIG. 14. In some embodiments, the dielectric material 1426 disposed between the interconnect structures 1428 in different ones of the interconnect layers 1406-1410 may have different compositions; in other embodiments, the composition of the dielectric material 1426 between different interconnect layers 1406-1410 may be the same.

A first interconnect layer 1406 (referred to as Metal 1 or “M1”) may be formed directly on the device layer 1404. In some embodiments, the first interconnect layer 1406 may include trench structures 1428a and/or via structures 1428b, as shown. The trench structures 1428a of the first interconnect layer 1406 may be coupled with contacts (e.g., the S/D contacts 1424) of the device layer 1404.

A second interconnect layer 1408 (referred to as Metal 2 or “M2”) may be formed directly on the first interconnect layer 1406. In some embodiments, the second interconnect layer 1408 may include via structures 1428b to couple the trench structures 1428a of the second interconnect layer 1408 with the trench structures 1428a of the first interconnect layer 1406. Although the trench structures 1428a and the via structures 1428b are structurally delineated with a line within each interconnect layer (e.g., within the second interconnect layer 1408) for the sake of clarity, the trench structures 1428a and the via structures 1428b may be structurally and/or materially contiguous (e.g., simultaneously filled during a dual-damascene process) in some embodiments.

A third interconnect layer 1410 (referred to as Metal 3 or “M3”) (and additional interconnect layers, as desired) may be formed in succession on the second interconnect layer 1408 according to similar techniques and configurations described in connection with the second interconnect layer 1408 or the first interconnect layer 1406.

The IC device 1400 may include a solder resist material 1434 (e.g., polyimide or similar material) and one or more bond pads 1436 formed on the interconnect layers 1406-1410. The bond pads 1436 may be electrically coupled with the interconnect structures 1428 and configured to route the electrical signals of the transistor(s) 1440 to other external devices. For example, solder bonds may be formed on the one or more bond pads 1436 to mechanically and/or electrically couple a chip including the IC device 1400 with another component (e.g., a circuit board). The IC device 1400 may have other alternative configurations to route the electrical signals from the interconnect layers 1406-1410 than depicted in other embodiments. For example, the bond pads 1436 may be replaced by or may further include other analogous features (e.g., posts) that route the electrical signals to external components.

FIG. 15 is a cross-sectional side view of an IC device assembly 1500 that may include components having one or more transistor gate-channel arrangements with multiple dipole materials in accordance with any of the embodiments disclosed herein. The IC device assembly 1500 includes a number of components disposed on a circuit board 1502 (which may be, e.g., a motherboard). The IC device assembly 1500 includes components disposed on a first face 1540 of the circuit board 1502 and an opposing second face 1542 of the circuit board 1502; generally, components may be disposed on one or both faces 1540 and 1542. In particular, any suitable ones of the components of the IC device assembly 1500 may include any of the transistor gate stacks 100 disclosed herein (e.g., in any of the transistors 120 disclosed herein).

In some embodiments, the circuit board 1502 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1502. In other embodiments, the circuit board 1502 may be a non-PCB substrate.

The IC device assembly 1500 illustrated in FIG. 15 includes a package-on-interposer structure 1536 coupled to the first face 1540 of the circuit board 1502 by coupling components 1516. The coupling components 1516 may electrically and mechanically couple the package-on-interposer structure 1536 to the circuit board 1502 and may include solder balls (as shown in FIG. 15), male and female portions of a socket, an adhesive, an underfill material, and/or any other suitable electrical and/or mechanical coupling structure.

The package-on-interposer structure 1536 may include an IC package 1520 coupled to an interposer 1504 by coupling components 1518. The coupling components 1518 may take any suitable form for the application, such as the forms discussed above with reference to the coupling components 1516. Although a single IC package 1520 is shown in FIG. 15, multiple IC packages may be coupled to the interposer 1504; indeed, additional interposers may be coupled to the interposer 1504. The interposer 1504 may provide an intervening substrate used to bridge the circuit board 1502 and the IC package 1520. The IC package 1520 may be or include, for example, a die (the die 1302 of FIG. 13B), an IC device (e.g., the IC device 1400 of FIG. 14), or any other suitable component. Generally, the interposer 1504 may spread a connection to a wider pitch or reroute a connection to a different connection. For example, the interposer 1504 may couple the IC package 1520 (e.g., a die) to a ball grid array (BGA) of the coupling components 1516 for coupling to the circuit board 1502. In the embodiment illustrated in FIG. 15, the IC package 1520 and the circuit board 1502 are attached to opposing sides of the interposer 1504; in other embodiments, the IC package 1520 and the circuit board 1502 may be attached to a same side of the interposer 1504. In some embodiments, three or more components may be interconnected by way of the interposer 1504.

The interposer 1504 may be formed of an epoxy resin, a fiberglass-reinforced epoxy resin, a ceramic material, or a polymer material such as polyimide. In some implementations, the interposer 1504 may be formed of alternate rigid or flexible materials that may include the same materials described above for use in a semiconductor substrate, such as silicon, germanium, and other group III-V and group IV materials. The interposer 1504 may include metal interconnects 1508 and vias 1510, including but not limited to through-silicon vias (TSVs) 1506. The interposer 1504 may further include embedded devices 1514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1504. The package-on-interposer structure 1536 may take the form of any of the package-on-interposer structures known in the art.

The IC device assembly 1500 may include an IC package 1524 coupled to the first face 1540 of the circuit board 1502 by coupling components 1522. The coupling components 1522 may take the form of any of the embodiments discussed above with reference to the coupling components 1516, and the IC package 1524 may take the form of any of the embodiments discussed above with reference to the IC package 1520.

The IC device assembly 1500 illustrated in FIG. 15 includes a package-on-package structure 1534 coupled to the second face 1542 of the circuit board 1502 by coupling components 1528. The package-on-package structure 1534 may include an IC package 1526 and an IC package 1532 coupled together by coupling components 1530 such that the IC package 1526 is disposed between the circuit board 1502 and the IC package 1532. The coupling components 1528 and 1530 may take the form of any of the embodiments of the coupling components 1516 discussed above, and the IC packages 1526 and 1532 may take the form of any of the embodiments of the IC package 1520 discussed above. The package-on-package structure 1534 may be configured in accordance with any of the package-on-package structures known in the art.

FIG. 16 is a block diagram of an example computing device 1600 that may include one or more components including one or more transistor gate-channel arrangements with multiple dipole materials in accordance with any of the embodiments disclosed herein. For example, any suitable ones of the components of the computing device 1600 may include a die (e.g., the die 1302 (FIG. 13B)) having one or more transistors 120 including one or more transistor gate stacks 100. Any one or more of the components of the computing device 1600 may include, or be included in, an IC device 1400 (FIG. 14). Any one or more of the components of the computing device 1600 may include, or be included in, an IC device assembly 1500 (FIG. 15).

A number of components are illustrated in FIG. 16 as included in the computing device 1600, but any one or more of these components may be omitted or duplicated, as suitable for the application. In some embodiments, some or all of the components included in the computing device 1600 may be attached to one or more motherboards. In some embodiments, some or all of these components are fabricated onto a single system-on-a-chip (SoC) die.

Additionally, in various embodiments, the computing device 1600 may not include one or more of the components illustrated in FIG. 16, but the computing device 1600 may include interface circuitry for coupling to the one or more components. For example, the computing device 1600 may not include a display device 1612, but may include display device interface circuitry (e.g., a connector and driver circuitry) to which a display device 1612 may be coupled. In another set of examples, the computing device 1600 may not include an audio input device 1616 or an audio output device 1614 but may include audio input or output device interface circuitry (e.g., connectors and supporting circuitry) to which an audio input device 1616 or audio output device 1614 may be coupled.

The computing device 1600 may include a processing device 1602 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1602 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1600 may include a memory 1604, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1604 may include memory that shares a die with the processing device 1602. This memory may be used as cache memory and may include embedded dynamic random-access memory (eDRAM) or spin transfer torque magnetic random-access memory (STT-MRAM).

In some embodiments, the computing device 1600 may include a communication chip 1606 (e.g., one or more communication chips). For example, the communication chip 1606 may be configured for managing wireless communications for the transfer of data to and from the computing device 1600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1606 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 1606 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 1606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1606 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1606 may operate in accordance with other wireless protocols in other embodiments. The computing device 1600 may include an antenna 1608 to facilitate wireless communications and/or to receive other wireless communications (such as AM or FM radio transmissions).

In some embodiments, the communication chip 1606 may manage wired communications, such as electrical, optical, or any other suitable communication protocols (e.g., the Ethernet). As noted above, the communication chip 1606 may include multiple communication chips. For instance, a first communication chip 1606 may be dedicated to shorter-range wireless communications such as Wi-Fi or Bluetooth, and a second communication chip 1606 may be dedicated to longer-range wireless communications such as global positioning system (GPS), EDGE, GPRS, CDMA, WiMAX, LTE, EV-DO, or others. In some embodiments, a first communication chip 1606 may be dedicated to wireless communications, and a second communication chip 1606 may be dedicated to wired communications.

The computing device 1600 may include a battery/power circuitry 1610. The battery/power circuitry 1610 may include one or more energy storage devices (e.g., batteries or capacitors) and/or circuitry for coupling components of the computing device 1600 to an energy source separate from the computing device 1600 (e.g., AC line power).

The computing device 1600 may include a display device 1612 (or corresponding interface circuitry, as discussed above). The display device 1612 may include any visual indicators, such as a heads-up display, a computer monitor, a projector, a touchscreen display, a liquid crystal display (LCD), a light-emitting diode display, or a flat panel display, for example.

The computing device 1600 may include an audio output device 1614 (or corresponding interface circuitry, as discussed above). The audio output device 1614 may include any device that generates an audible indicator, such as speakers, headsets, or earbuds, for example.

The computing device 1600 may include an audio input device 1616 (or corresponding interface circuitry, as discussed above). The audio input device 1616 may include any device that generates a signal representative of a sound, such as microphones, microphone arrays, or digital instruments (e.g., instruments having a musical instrument digital interface (MIDI) output).

The computing device 1600 may include an other output device 1618 (or corresponding interface circuitry, as discussed above). Examples of the other output device 1618 may include an audio codec, a video codec, a printer, a wired or wireless transmitter for providing information to other devices, or an additional storage device.

The computing device 1600 may include an other input device 1620 (or corresponding interface circuitry, as discussed above). Examples of the other input device 1620 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1600 may include a GPS device 1622 (or corresponding interface circuitry, as discussed above). The GPS device 1622 may be in communication with a satellite-based system and may receive a location of the computing device 1600, as known in the art.

The computing device 1600 may include a security interface device 1624. The security interface device 1624 may include any device that provides security features for the computing device 1600 or for any individual components therein (e.g., for the processing device 1602 or for the memory 1604). Examples of security features may include authorization, access to digital certificates, access to items in keychains, etc. Examples of the security interface device 1624 may include a software firewall, a hardware firewall, an antivirus, a content filtering device, or an intrusion detection device.

In some embodiments, the computing device 1600 may include a temperature detection device 1626 and a temperature regulation device 1628.

The temperature detection device 1626 may include any device capable of determining temperatures of the computing device 1600 or of any individual components therein (e.g., temperatures of the processing device 1602 or of the memory 1604). In various embodiments, the temperature detection device 1626 may be configured to determine temperatures of an object (e.g., the computing device 1600, components of the computing device 1600, devices coupled to the computing device, etc.), temperatures of an environment (e.g., a data center that includes, is controlled by, or otherwise associated with the computing device 1600), and so on. The temperature detection device 1626 may include one or more temperature sensors. Different temperature sensors of the temperature detection device 1626 may have different locations within and around the computing device 1600. A temperature sensor may generate data (e.g., digital data) representing detected temperatures and provide the data to another device, e.g., to the temperature regulation device 1628, the processing device 1602, the memory 1604, etc. In some embodiments, a temperature sensor of the temperature detection device 1626 may be turned on or off, e.g., by the processing device 1602 or an external system. The temperature sensor detects temperatures when it is on and does not detect temperatures when it is off. In other embodiments, a temperature sensor of the temperature detection device 1626 may detect temperatures continuously and automatically or detect temperatures at predefined times or at times triggered by an event associated with the computing device 1600 or any components therein.

The temperature regulation device 1628 may include any device configured to change (e.g., decrease) temperatures, e.g., based on one or more target temperatures and/or based on temperature measurements performed by the temperature detection device 1626. A target temperature may be a preferred temperature. A target temperature may depend on a setting in which the computing device 1600 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 1600 can be different. In some embodiments, cooling provided by the temperature regulation device 1628 may be a multi-stage process with temperatures ranging from room temperature to 4K or lower.

In some embodiments, the temperature regulation device 1628 may include one or more cooling devices. Different cooling device may have different locations within and around the computing device 1600. A cooling device of the temperature regulation device 1628 may be associated with one or more temperature sensors of the temperature detection device 1626 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 1600 is satisfied. In response to determining that one or more temperature-related condition associated with the temperature of the computing device 1600 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 1628 may operate with various cooling mechanisms, such as evaporation cooling, radiation cooling, conduction cooling, convection cooling, other cooling mechanisms, or any combination thereof. A cooling device of the temperature regulation device 1628 may include a cooling agent, such as a water, oil, liquid nitrogen, liquid helium, etc. In some embodiments, the temperature regulation device 1628 may be, for example, a dilution refrigerator, a helium-3 refrigerator, or a liquid helium refrigerator. In some embodiments, the temperature regulation device 1628 or any portions thereof (e.g., one or more of the individual cooling devices) may be connected to the computing device 1600 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 1600 (or components thereof) can be reduced, while the computing efficiency may be improved. For example, when the computing device 1600 (or components thereof) operates at lower temperatures, energy dissipation (e.g., heat dissipation) may be reduced. Further, energy consumed by semiconductor components (e.g., energy needed for switching transistors of any of the components of the computing device 1600) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy correlates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 1600 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1600 may be any other electronic device that processes data.

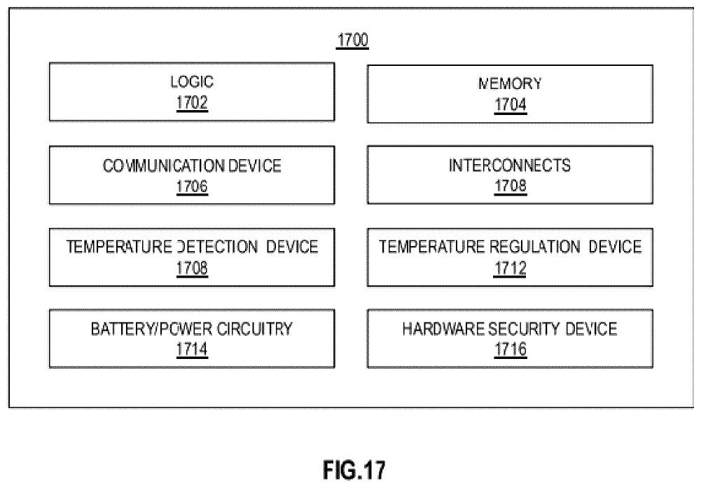

FIG. 17 is a block diagram of an example processing device 1700 that may include one or more transistor gate-channel arrangements with multiple dipole materials in accordance with any of the embodiments disclosed herein. For example, any suitable ones of the components of the processing device 1700 may include a die (e.g., the die 1302 (FIG. 13B)) having one or more transistors 120 including one or more transistor gate stacks 100. Any one or more of the components of the processing device 1700 may include, or be included in, an IC device 1400 (FIG. 14). Any one or more of the components of the processing device 1700 may include, or be included in, an IC device assembly 1500 (FIG. 15). Any one or more of the components of the processing device 1700 may include, or be included in, a computing device 1600 (FIG. 16); for example, the processing device 1700 may be the processing device 1602 of the computing device 1600.

A number of components are illustrated in FIG. 17 as included in the processing device 1700, but any one or more of these components may be omitted or duplicated, as suitable for the application. In some embodiments, some or all of the components included in the processing device 1700 may be attached to one or more motherboards. In some embodiments, some or all of these components are fabricated on a single SoC die or coupled to a single support structure, e.g., to a single carrier substrate.

Additionally, in various embodiments, the processing device 1700 may not include one or more of the components illustrated in FIG. 17, but the processing device 1700 may include interface circuitry for coupling to the one or more components. For example, the processing device 1700 may not include a memory 1704, but may include display device interface circuitry (e.g., a connector and driver circuitry) to which a memory 1704 may be coupled.

The processing device 1700 may include logic circuitry 1702 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 1702 may include one or more circuits responsible for read/write operations with respect to the data stored in the memory 1704. To that end, the logic circuitry 1702 may include one or more I/O ICs configured to control access to data stored in the memory 1704.

In some embodiments, the logic circuitry 1702 may include one or more high-performance compute dies, configured to perform various operations with respect to data stored in the memory 1704 (e.g., arithmetic and logic operations, pipelining of data from one or more memory dies of the memory 1704, and possibly also data from external devices/chips). In some embodiments, the logic circuitry 1702 may be configured to only control I/O access to data but not perform any operations on the data. In some embodiments, the logic circuitry 1702 may implement ICs configured to implement I/O control of data stored in the memory 1704, assemble data from the memory 1704 for transport (e.g., transport over a central bus) to devices/chips that are either internal or external to the processing device 1700, etc. In some embodiments, the logic circuitry 1702 may not be configured to perform any operations on the data besides I/O and assembling for transport to the memory 1704.

The processing device 1700 may include a memory 1704, which may include one or more ICs configure to implement memory circuitry (e.g., ICs implementing one or more of memory devices, memory arrays, control logic configured to control the memory devices and arrays, etc.). In some embodiments, the memory 1704 may be implemented substantially as described above with reference to the memory 1604 (FIG. 16). In some embodiments, the memory 1704 may be a designated device configured to provide storage functionality for the components of the processing device 1700 (i.e., local), while the memory 1604 may be configured to provide system-level storage functionality for the entire computing device 1600 (i.e., global). In some embodiments, the memory 1704 may include memory that shares a die with the logic circuitry 1702.

In some embodiments, the memory 1704 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 1704 may be a memory that is not divided into hierarchical layer or levels in terms of access of its data.

In some embodiments, the memory 1704 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 1704 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 1704 may be arranged.

The processing device 1700 may include a communication device 1706, which may be implemented substantially as described above with reference to the communication chip 1606 (FIG. 16). In some embodiments, the communication device 1706 may be a designated device configured to provide communication functionality for the components of the processing device 1700 (i.e., local), while the communication chip 1606 may be configured to provide system-level communication functionality for the entire computing device 1600 (i.e., global).

The processing device 1700 may include interconnects 1708, which may include any element or device that includes an electrically conductive material for providing electrical connectivity to one or more components of, or associated with, a processing device 1700 or/and between various such components. Examples of the interconnects 1708 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 1700 may include a temperature detection device 1710 which may be implemented substantially as described above with reference to the temperature detection device 1626 (FIG. 16) but configured to determine temperatures on a more local scale, i.e., of the processing device 1700 of components thereof. In some embodiments, the temperature detection device 1710 may be a designated device configured to provide temperature detection functionality for the components of the processing device 1700 (i.e., local), while the temperature detection device 1626 may be configured to provide system-level temperature detection functionality for the entire computing device 1600 (i.e., global).

The processing device 1700 may include a temperature regulation device 1712 which may be implemented substantially as described above with reference to the temperature regulation device 1628 (FIG. 16) but configured to regulate temperatures on a more local scale, i.e., of the processing device 1700 of components thereof. In some embodiments, the temperature regulation device 1712 may be a designated device configured to provide temperature regulation functionality for the components of the processing device 1700 (i.e., local), while the temperature regulation device 1628 may be configured to provide system-level temperature regulation functionality for the entire computing device 1600 (i.e., global).

The processing device 1700 may include a battery/power circuitry 1714 which may be implemented substantially as described above with reference to the battery/power circuitry 1610 (FIG. 16). In some embodiments, the battery/power circuitry 1714 may be a designated device configured to provide battery/power functionality for the components of the processing device 1700 (i.e., local), while the battery/power circuitry 1610 may be configured to provide system-level battery/power functionality for the entire computing device 1600 (i.e., global).

The processing device 1700 may include a hardware security device 1716 which may be implemented substantially as described above with reference to the security interface device 1624 (FIG. 16). In some embodiments, the hardware security device 1716 may be a physical computing device configured to safeguard and manage digital keys, perform encryption and decryption functions for digital signatures, authentication, and other cryptographic functions. In some embodiments, the hardware security device 1716 may include one or more secure cryptoprocessors chips.

The following paragraphs provide various examples of the embodiments disclosed herein.
Example 1 provides an IC structure that includes a transistor gate-channel arrangement, including a channel material and a transistor gate stack. The transistor gate stack includes a gate electrode material and a multi-dipole gate structure between the gate electrode material and the channel material. The multi-dipole gate structure includes a first dipole material having a first material composition and a second dipole material having a second material composition, where the first material composition is different from the second material composition, and where one of the first dipole material and the second dipole material is a P-shifter dipole material and another one of the first dipole material and the second dipole material is an N-shifter dipole material.
Example 2 provides the IC structure according to example 1, where the P-shifter dipole material includes one or more of aluminum, vanadium, niobium, titanium, boron, gallium, molybdenum, chromium, cobalt, tantalum, or tungsten.
Example 3 provides the IC structure according to example 1, where the P-shifter dipole material includes one or more of aluminum, niobium, or vanadium.
Example 4 provides the IC structure according to any one of examples 1-3, where the N-shifter dipole material includes one or more of lanthanum, molybdenum, strontium, scandium, magnesium, manganese, barium, cerium, erbium, dysprosium, europium, gadolinium, holium, yttrium, lutetium, neodynium, samarium, or terbium.
Example 5 provides the IC structure according to any one of examples 1-3, where the N-shifter dipole material includes one or more of lanthanum, scandium, or yttrium.
Example 6 provides the IC structure according to any one of examples 1-5, where the multi-dipole gate structure further includes a high-k dielectric.
Example 7 provides the IC structure according to example 6, where the first dipole material and the second dipole material are diffused in the high-k dielectric.
Example 8 provides the IC structure according to example 7, where concentration of the first dipole material in the multi-dipole gate structure decreases closer to the channel material.
Example 9 provides the IC structure according to any one of examples 1-8, where the multi-dipole gate structure includes an interface layer and a high-k dielectric, the interface layer is between the channel material and the high-k dielectric, the high-k dielectric is between the interface layer and the gate electrode material, and concentration of atoms of the first dipole material is highest at an interface between the interface layer and the high-k dielectric, and gradually decreases away from the interface.
Example 10 provides the IC structure according to example 9, where concentration of atoms of the second dipole material is highest at an interface between the interface layer and the high-k dielectric, and gradually decreases away from the interface.
Example 11 provides an IC structure, including a substrate and a stack of nanoribbons of one or more semiconductor materials over the substrate, where a portion of at least one of the nanoribbons of the stack is a channel region of a transistor and where the transistor includes a transistor gate stack. The transistor gate stack includes a gate electrode material, an interface layer in contact with the channel region, a high-k dielectric between the interface layer and the gate electrode material, atoms of a first dipole material, and atoms of a second dipole material, different from the first dipole material.
Example 12 provides the IC structure according to example 11, where concentration of the atoms of the first dipole material is highest at an interface between the interface layer and the high-k dielectric, and gradually decreases away from the interface.
Example 13 provides the IC structure according to any one of examples 11-12, where concentration of the atoms of the second dipole material is highest at an interface between the interface layer and the high-k dielectric, and gradually decreases away from the interface.
Example 14 provides the IC structure according to any one of examples 11-13, where the first dipole material is aluminum, niobium, or vanadium.
Example 15 provides the IC structure according to any one of examples 11-14, where the second dipole material is lanthanum, scandium, or yttrium.
Example 16 provides the IC structure according to any one of examples 11-15, where the transistor gate stack wraps around the channel region.
Example 17 provides the IC structure according to any one of examples 11-16, where the transistor is a first transistor, and a portion of at least one of the nanoribbons of the stack is a channel region of a second transistor, the second transistor including a transistor gate stack that excludes the atoms of the first dipole material, the atoms of the second dipole material, or both the atoms of the first dipole material and the atoms of the second dipole material.
Example 18 provides a method of manufacturing an IC structure including a transistor, the method including providing an interface layer; providing a high-k dielectric forming an interface with the interface layer; providing a first dipole material over the high-k dielectric; providing a second dipole material over the first dipole material, where one of the first dipole material and the second dipole material is a P-shifter dipole material and another one of the first dipole material and the second dipole material is an N-shifter dipole material; providing a cap sealing the first dipole material and the second dipole material; performing an anneal to diffuse atoms of the first dipole material and atoms of the second dipole material into the high-k dielectric; and following the anneal, providing a gate electrode material so that the high-k dielectric is between the interface layer and the gate electrode material.
Example 19 provides the method according to example 18, where, following the anneal, concentration of the atoms of the first dipole material or the atoms of the second dipole material is highest at an interface between the interface layer and the high-k dielectric.
Example 20 provides the method according to any one of examples 18-20, further including providing a channel material such that the interface layer is between the channel material and the high-k dielectric.
Example 21 provides the method according to any one of examples 18-20, where the IC structure is an IC structure according to any one of the preceding examples.
Example 22 provides an IC package that includes an IC die including an IC structure according to any one of examples 1-17; and a further IC component, coupled to the IC die.
Example 23 provides the IC package according to example 22, where the further IC component includes a package substrate.
Example 24 provides the IC package according to example 22, where the further IC component includes an interposer.
Example 25 provides the IC package according to example 22, where the further IC component includes a further IC die.
Example 26 provides a computing device that includes a carrier substrate and an IC structure coupled to the carrier substrate, where the IC structure is an IC structure according to any one of examples 1-17, or the IC structure is included in the IC package according to any one of examples 22-25.
Example 27 provides the computing device according to example 26, where the computing device is a wearable or handheld computing device.
Example 28 provides the computing device according to examples 26 or 27, where the computing device further includes one or more communication chips.
Example 29 provides the computing device according to any one of examples 26-28, where the computing device further includes an antenna.
Example 30 provides the computing device according to any one of examples 26-29, where the carrier substrate is a motherboard.
Example 31 provides the IC structure according to any one of examples 1-17, where the IC structure includes or is a part of a central processing unit.
Example 32 provides the IC structure according to any one of examples 1-31, where the IC structure includes or is a part of a memory device, e.g., a high-bandwidth memory device.
Example 33 provides the IC structure according to any one of examples 1-32, where the IC structure includes or is a part of a logic circuit.
Example 34 provides the IC structure according to any one of examples 1-33, where the IC structure includes or is a part of input/output circuitry.
Example 35 provides the IC structure according to any one of examples 1-34, where the IC structure includes or is a part of an FPGA transceiver.
Example 36 provides the IC structure according to any one of examples 1-35, where the IC structure includes or is a part of an FPGA logic.
Example 37 provides the IC structure according to any one of examples 1-36, where the IC structure includes or is a part of a power delivery circuitry.
Example 38 provides the IC structure according to any one of examples 1-37, where the IC structure includes or is a part of a III-V amplifier.
Example 39 provides the IC structure according to any one of examples 1-38, where the IC structure includes or is a part of PCIE circuitry or DDR transfer circuitry.

1. An integrated circuit (IC) structure, comprising:
a channel material;
a gate electrode material; and
a multi-dipole gate structure between the gate electrode material and the channel material,
wherein the multi-dipole gate structure includes a first dipole material having a first material composition and a second dipole material having a second material composition, wherein the first material composition is different from the second material composition, and wherein one of the first dipole material and the second dipole material is a P-shifter dipole material and another one of the first dipole material and the second dipole material is an N-shifter dipole material.

2. The IC structure according to claim 1, wherein the P-shifter dipole material includes one or more of aluminum, vanadium, niobium, titanium, boron, gallium, molybdenum, chromium, cobalt, tantalum, or tungsten.

3. The IC structure according to claim 1, wherein the P-shifter dipole material includes one or more of aluminum, niobium, or vanadium.

4. The IC structure according to claim 1, wherein the N-shifter dipole material includes one or more of lanthanum, molybdenum, strontium, scandium, magnesium, manganese, barium, cerium, erbium, dysprosium, europium, gadolinium, holium, yttrium, lutetium, neodynium, samarium, or terbium.

5. The IC structure according to claim 1, wherein the N-shifter dipole material includes one or more of lanthanum, scandium, or yttrium.

6. The IC structure according to claim 1, wherein the multi-dipole gate structure further includes a high-k dielectric.

7. The IC structure according to claim 6, wherein the first dipole material and the second dipole material are diffused in the high-k dielectric.

8. The IC structure according to claim 7, wherein concentration of the first dipole material in the multi-dipole gate structure decreases closer to the channel material.

9. The IC structure according to claim 1, wherein:
the multi-dipole gate structure includes an interface layer and a high-k dielectric,
the interface layer is between the channel material and the high-k dielectric,
the high-k dielectric is between the interface layer and the gate electrode material, and
concentration of atoms of the first dipole material is highest at an interface between the interface layer and the high-k dielectric, and gradually decreases away from the interface.

10. The IC structure according to claim 9, wherein concentration of atoms of the second dipole material is highest at an interface between the interface layer and the high-k dielectric, and gradually decreases away from the interface.

11. An integrated circuit (IC) structure, comprising:
a substrate; and
a stack of nanoribbons of one or more semiconductor materials over the substrate,
wherein a portion of at least one of the nanoribbons of the stack is a channel region of a transistor, the transistor comprising a transistor gate stack that includes:
a gate electrode material,
an interface layer in contact with the channel region,
a high-k dielectric between the interface layer and the gate electrode material,
atoms of a first dipole material, and
atoms of a second dipole material, different from the first dipole material.

12. The IC structure according to claim 11, wherein concentration of the atoms of the first dipole material is highest at an interface between the interface layer and the high-k dielectric, and gradually decreases away from the interface.

13. The IC structure according to claim 11, wherein concentration of the atoms of the second dipole material is highest at an interface between the interface layer and the high-k dielectric, and gradually decreases away from the interface.

14. The IC structure according to claim 11, wherein the first dipole material is aluminum, niobium, or vanadium.

15. The IC structure according to claim 11, wherein the second dipole material is lanthanum, scandium, or yttrium.

16. The IC structure according to claim 11, wherein the transistor gate stack wraps around the channel region.

17. The IC structure according to claim 11, wherein:
the transistor is a first transistor, and
a portion of at least one of the nanoribbons of the stack is a channel region of a second transistor, the second transistor comprising a transistor gate stack that excludes the atoms of the first dipole material, the atoms of the second dipole material, or both the atoms of the first dipole material and the atoms of the second dipole material.

18. A method of manufacturing a transistor, the method comprising:
providing an interface layer;
providing a high-k dielectric forming an interface with the interface layer;
providing a first dipole material over the high-k dielectric;
providing a second dipole material over the first dipole material, wherein one of the first dipole material and the second dipole material is a P-shifter dipole material and another one of the first dipole material and the second dipole material is an N-shifter dipole material;
providing a cap sealing the first dipole material and the second dipole material;
performing an anneal to diffuse atoms of the first dipole material and atoms of the second dipole material into the high-k dielectric; and
following the anneal, providing a gate electrode material so that the high-k dielectric is between the interface layer and the gate electrode material.

19. The method according to claim 18, wherein, following the anneal, concentration of the atoms of the first dipole material or the atoms of the second dipole material is highest at an interface between the interface layer and the high-k dielectric.

20. The method according to claim 18, further comprising:
providing a channel material such that the interface layer is between the channel material and the high-k dielectric.
